(19) United States
(12) Patent Application Publication
(10) Pub. No.: US 2002/0133940 A1
(43) Pub. Date: Sep. 26, 2002

(54) Electric-component supplying method and device, and electric-component mounting method and system

(75) Inventors: Sumio Kadomatsu, Okazaki-shi (JP); Shinsuke Suhara, Kariya-shi (JP); Takayoshi Kawai, Okazaki-shi (JP)

Correspondence Address: OLIFF & BERRIDGE, PLC, P.O. BOX 19928, ALEXANDRIA, VA, 22320, US

(73) Assignee: FUJI MACHINE MFG. CO., LTD, Chiryu-shi (JP)

(21) Appl. No.: 10/101,912

(22) Filed: Mar. 21, 2002

(30) Foreign Application Priority Data
Mar. 26, 2001 (JP) 2001-087759

(51) Int. Cl. B23P 19/00; H05K 3/30

(52) U.S. Cl. 29/832; 29/740; 29/771

(57) ABSTRACT

Method and device for supplying electric components, using two component supply tables each including a feeder support structure and a plurality of component feeders mounted on the feeder support structure, each component feeder accommodating a group of electric components of one kind and arranged to successively supply the electronic components such that a combination of electric components of different kinds that can be supplied from the component feeders on one of the two tables is the same as that of electric components of different kinds that can be supplied from the component feeders on the other table, and wherein a first table which is one of the two tables is operated to supply the electric components, while a second table which is the other table is held in an off state, and the first table is held in an off state while the second table is operated to supply the electric components, after the first table has been exhausted of the electric components of any kind, and wherein the first ands second tables cooperate to supply the electric components after the second table has been exhausted of the electric components of any kind. Component mounting method and system using the component supplying method and device are also disclosed.

This application is based on Japanese Patent Application No. 2001-087759 filed on Mar. 26, 2001, the contents of which are incorporated hereinto by reference.

### BACKGROUND OF THE INVENTION

1. Field of the Invention

The present invention relates in general to method and device for supplying electric components (including electronic components) and method and system for mounting the electric components, and more particularly to method and device for supplying electric components from two component supply tables.

2. Discussion of Related Art

JP-B2-8-21791 discloses an example of an electric-component supplying device equipped with two component supply tables arranged to supply electric components (typically, electronic components). Each component supply table includes a feeder support structure, and a plurality of feeders mounted on the feeder support structure. Each of the feeders accommodates a multiplicity of electric components of the same kind or type. For instance, an electric-component supplying device equipped with such two component supply tables is used in an electric-component mounting system, to supply a component-mounting device with electric components, in various modes of operation. Where the number of the kinds of electric components to be mounted on each printed-wiring board or the number of the electric components to be mounted is relatively small so that all of the feeders used to supply the electric components can be mounted on one component supply table, for example, the same set of feeders accommodating different kinds of electric components is mounted on each of the two component supply tables. In this case, one of the two component supply tables is used until all of the electric components of any kind accommodated in any feeder on that one component supply table have been supplied to the electric-component mounting device, and is replaced by the other component supply table, which is then used to supply the electric components. The exhausted component supply table is moved from a working area to a standby area, and is replenished with a new set of feeders accommodating the electric components. For instance, the operator of the electric-component mounting system removes the exhausted feeders and mount the new feeders accommodating the electric components. Thus, the two component supply tables are alternately used to supply the component-mounting device with the desired electric components, such that the exhausted component supply table is replaced by the other component supply table re-loaded with the electric components. The alternate use of the two component supply tables on which the same sets of feeders accommodating respective kinds of electric components are mounted permits a continued operation of supplying the component-mounting device with the electric components, without an interruption of the electric-component supplying device, even when one of the two component supply tables has been exhausted.

However, the operation of the electric-component supply device which is arranged to alternately use two component supply tables for supplying the electric components as described above is required to be interrupted or suspended under some conditions. For instance, the presently used component supply table has been exhausted before the other component supply table located in the standby area has been re-loaded or replenished with the electric components. In this instance, the operation of the electric-component supplying device must be interrupted until the re-loading of the component supply table in the standby area is completed. This interruption seriously lowers the efficiency of mounting of the electric components on the printed-wiring boards, particularly in an electric-component mounting line which consists of a plurality of electric-components mounting systems each using an electric-component supplying device equipped with two component supply tables. In this electric-component mounting line, the re-loading of the exhausted component supply table may be required to be effected simultaneously in two or more of the electric-component mounting systems, and the re-loading operation in any electric-component mounting system may not be completed by the operator before the presently used component supply table has been exhausted. In this event, the operation of the relevant electric-component supplying device must be interrupted, and the component mounting efficiency is inevitably lowered.

### SUMMARY OF THE INVENTION

It is therefore an object of the present invention to minimize a time of interruption of an operation of an electric-component supplying device which uses two component supply tables for supplying electric components. This above object may be achieved according to any one of the following modes of the present invention in the form of an electric-component supplying method, an electric-component mounting method, an electric-component supplying device, or an electric-component mounting system. Each of the following modes of the invention is numbered like the appended claims and depends from the other mode or modes, where appropriate, to indicate and clarify possible combinations of elements or technical features. It is to be understood that the present invention is not limited to the technical features or any combinations thereof which will be described for illustrative purpose only. It is to be further understood that a plurality of elements or features included in any one of the following modes of the invention are not necessarily provided all together, and that the invention may be embodied without some of the elements or features described with respect to the same mode.

(1) A method of supplying electric components, comprising:

a preparing step of preparing two component supply tables each including a feeder support structure and a plurality of component feeders mounted on the feeder support structure, each of the plurality of component feeders accommodating a group of electric components of one kind and arranged to successively supply the electronic components from a component-supply portion thereof such that a combination of electric components of different kinds that can be supplied from the plurality of component feeders on one of the two component supply tables is the same as that of electric components of different kinds that can be supplied from the plurality of component feeders on the other component supply table;

a first component-supplying step in which a first table which is one of the two component supply tables is operated to supply the electric components, while a second table which is the other of the two component supply tables is held in an off state;

a second component-supplying step in which the first table is held in an off state while the second table is operated to supply the electric components, after the first table has been exhausted of the electric components of any kind; and

a third component-supplying step in which the first and second tables cooperate to supply the electric components after the second table has been exhausted of the electric components of any kind.

Each of the component feeders may include a component-accommodating portion and a component-feeding portion, so that the electric components accommodated in the component-accommodating portion are fed by a feeding device provided in the component-feeding portion, so as to be successively positioned at the component-supply portion. The electric components may be accommodated in a carrier tape such that the electric components are arranged at a predetermined pitch in the direction of length of the carrier tape. In this case, the feeding device is a tape feeding device arranged to feed the carrier tape so that the electric components are successively fed to the component-supply portion of the component feeder, and the component accommodating portion is a portion of the component feeder in which the carrier tape is accommodated, while the component feeding portion is a portion of the component feeder in which the tape feeding device is provided. Alternatively, the electric components may be accommodated in bulk in the component-accommodating portion. In this case, the electric components are fed to the component-supply portion by any suitable feeding device which utilizes a belt conveyor, an air stream, a ramp or vibrating means. The component-accommodating portion and the component-feeding portion of each component feeder may be formed integrally with each other or movable relative to each other.

The exhaustion of each of the first and second tables of the electric components of any kind is interpreted to mean not only a case where all of the electric components of a given kind have been supplied from the relevant table, but also a case where the number of the electric component of the relevant kind left on the relevant table has become smaller than a predetermined value. Where each component feeder is arranged to feed a carrier tape in which the electric components of the same kind are arranged at a predetermined pitch, so that the electric components are successively positioned at the component-supply portion, the component feeder in the form of a tape feeder accommodating the electric components of the same kind is considered to have been exhausted, when the unused length of the carrier tape has become smaller than a predetermined lower limit below which the new carrier tape is required to be spliced to the trailing end of the presently used carrier tape. In this case, the table including the component feeder (tape feeder) which has been exhausted need not be immediately replaced by the other table, and may be replaced by the other table after all of the predetermined electric components to be supplied have been supplied from the table which includes the exhausted component feeder.

Where a plurality of component feeders accommodating the electric components of the same kind are mounted on each of the two tables, the relevant tape is considered to have been exhausted of the electric components of this kind, when all of the plurality of component feeders have been exhausted, that is, when all of the electric components have been supplied from all of those components feeders, or the number of the electric components left in the last used one of those component feeders (the unused length of the carrier tape) has become smaller than a predetermined value.

Even if the first component supply table has been exhausted of the electric components of one kind while the second component supply table has been exhausted of the electric components of another kind, the first and second tables can cooperate to supply the electric components of all of the desired kinds, provided the electric components of the kind absent on each of the two tables are present or available on the other table. Accordingly, the cooperative operations of the first and second component supply tables permit the necessary components to be continuously supplied, without interrupting a supply of the electric components, even after the two tables have been exhausted of the electric components of different kinds. Therefore, a production line including a plurality of systems such as a plurality of electric-component mounting systems, each of which includes a component supplying device capable of practicing the present component supplying method, can be continuously operated without an interruption, even in the event of exhaustion of the two component supply tables of respective different kinds of electric components in the component supplying device of any system. Thus, the present component supplying method makes it possible to reduce a need of interrupting the operation of the component supplying device of any system, thereby reducing the deterioration of efficiency of supply of the electric components by the component supplying device.

In the second component-supplying step, the first table may or may not be re-loaded with the electric components of the exhausted kind or kinds. In the third component-supplying step, too, one of the first and second component supply tables may be temporarily held in the off state. In this case, the table in the off state may be re-loaded with the electric components of the exhausted kind or kinds. The re-loading of the table in the off state permits a further reduction of a need of interrupting the supply of the electric components from the two tables, thereby making it possible to shorten the required time duration of the interruption. The re-loading of the table may be effected in various manners. For instance, the re-loading of the table is effected by re-loading each exhausted component feeder with the electric components of the corresponding kind or by replacing the exhausted component feeder with the new one. Where a pallet on which the component feeders are set is mounted on the table, this pallet having the exhausted component feeder or feeders is replaced with a new patent.

(2) The method according to the above mode (1), further comprising a transition-permitting step implemented upon exhaustion of the second table of the electric components of any kind, to check if the first table is able to supply the electric components of the kind exhausted on the second table, and permit a transition from the second component-supplying step to the third component-supplying step.

The third component-supplying step may be terminated when it is detected that both of the first and second tables have been exhausted of the electric components of the same kind one of which is required to be supplied. In the above mode (2), however, the transition-permitting step is implemented before initiation of the third component-supplying step, to check if the first table is able to supply the components of the kind exhausted on the second table, that is, to check if it is possible to continue supplying the necessary components. This transition-permitting step prevents unnecessary initiation of the third component-supplying step where the first table is not able to supply the components of the kind exhausted on the second table.

(3) The method according to the above mode (1) or (2), further comprising a ceasing step of automatically ceasing a supply of the electric components from the first and second tables, when the first and second tables have become unable to supply the electric components of the same kind.

The automatic ceasing of the supply of the electric components from the tables prevents unnecessary operations of the tables, where the components of the desired kind that are not available on either of the two tables. Accordingly, it is possible to prevent an unnecessary operation of a device which is arranged to receive the electric components from a component supplying device which includes the first and second tables.

(4) The method according to the above mode (3), wherein the ceasing step further comprises informing an operator of a system including the first and second tables, that the supply of the electric components from the first and second tables has been automatically ceased.

A suitable indicator device may be used to inform the operator in a suitable manner that the supply of the electric components from the tables has been automatically ceased. The indicator device may be a buzzer or any other alarming or warning device capable of generating an audible alarming signal, a lamp device capable of generating an optical signal such as continuous or flickering operation of an indicator light, a display device capable of providing a visible indication on a display screen, or a voice generator capable of generating an audible message.

Since the operator is informed of the automatic ceasing of the supply of the electric components from the tables, the operator can take a suitable measure in a short time, to deal with the ceasing of the supply.

(5) The method according to any one of the above modes (1)-(4), wherein the third component-supplying step is implemented such that said first table is primarily used to supply the necessary electric components, and the second table is used to supply only the electric components of at least one kind which cannot be supplied by the first table.

(6) The method according to any one of the above modes (1)-(5), wherein the third component-supplying step is implemented such that the second table is primarily used to supply the necessary electric components, and the first table is used to supply the only the electric components of at least one kind which cannot be supplied by said second table.

In the method of the above mode (5) including the feature of the above mode (6), the third component-supply step is implemented in one of: (a) a first mode wherein after the second table operated in the second component-supplying step has been exhausted of the electric components of any kind, the first table is first primarily used as a main component supply table, and the second table is then used as the main component supply table when the first table which has been used as the main component supply table has been exhausted of the electric components of any kind, the first table being then used as the main component supply table again when the second table has been exhausted of the electric components of any kind, the first and second tables being subsequently used alternately as the main component supply table in the same manner as described above; and (b) a second mode wherein the second table is first used as a main component supply table, and the first table is then used as the main component supply table when the second table has been exhausted of the electric components of any kind, the first and second tables being subsequently used alternately as the main component supply table in the same manner as described above.

(7) The method according to any one of the above modes (1)-(6), wherein the plurality of component feeders of each of the first and second tables includes at least one set of component feeders, each of the above-indicated at least one set consisting of a plurality of component feeders which accommodate the electric components of one kind, and wherein one of the first and second tables is used as an operating table when all of the plurality of component feeders of any one of the above-indicated at least one set of the other of the first and second tables have been exhausted of the electric components.

If the component feeders of each of the first and second tables accommodate the same number of electric components of different kinds, there is a possibility that the component feeder accommodating the electric components of one kind has been exhausted in a shorter time than the other component feeders accommodating the electric components of the other kinds. Where the electric components of different kinds having the same size are mounted on a printed-wiring board such that a plurality of electric components of a specific one of the different kinds are mounted on the board while only one electric component of each of the other kinds is mounted on the board, for instance, the number of the component feeders of each table which accommodate the electric components of that specific one kind is desirably made larger than those of the component feeders which accommodate the electric components of the other kinds. In this case, it is advantageous to control the first and second tables such that even when one of the component feeders of the operating table which accommodate the electric components of the same kind has been exhausted, this table is continuously used as the operating table until all of the component feeders accommodating the electric components of that kind have been exhausted.

(8) The method according to any one of the above modes (1)-(7), wherein the first and second tables are movable in a direction in which the component-supply portions of the plurality of component feeders of each of the first and second tables are arranged, and when one of the first and second tables is used as an operating table to supply the electric components of different kinds, the operating table is moved such that a selected one of the plurality of component feeders of the operating table is located at a predetermined component supply position, while the other of the first and second table is held in its off state.

In the method according to the above mode (8), the first and second tables are selectively used as the operating table to supply the electric components, by moving the selected table to move an appropriate one of its component feeders to the component supply position.

In the method according to the above mode (8), only the operating table is moved to supply the electric component, rather than the two component supply tables are moved simultaneously. Accordingly, a mass of a portion of a component supplying device including the two component supply tables, which portion is moved to supply the electric components, can be made comparatively small, and the magnitude of a vibration of the component supplying device which may take place due to starting and stopping of the movement of the device can be accordingly reduced, so that the selected component feeder can be located at the component supply position with a higher degree of accuracy than when both of the two tables are moved together. Further, the method according to the above mode (8) permits the exhausted component feeder or feeders of the non-operating table held in the off state, to be re-loaded with the electric components of the appropriate kind or replaced with the new ones.

(9) The method according to the above mode (8), wherein the third component-supplying step is implemented such that one of the first and second tables is used as an auxiliary component supply table to supply only the electric components of at least one kind exhausted on the other of the first and second tables, while the above-indicated other table is used as a main component supply table to supply the electric components of at least one kind which has been exhausted on the above-indicated one table and which is different from the at least one kind exhausted on the other table, if a total distance of movements of the above-indicated one table required to supply the electric components of the at least one kind exhausted on the above-indicated other table is smaller than a total distance of movements of the above-indicated other table required to supply the electric components of said at least one kind exhausted on the above-indicated one table.

Usually, the component feeders are arranged on the feeder support structure in a predetermined order in which the electric components of different kinds are supplied. In this case, the component supply table used as the operating table (main component supply table) is moved such that the component feeders are sequentially moved to the predetermined component supply position, in the order in which the component feeders are arranged on the feeder support structure. This arrangement is effective to reduce the required total distance of movements of the component supply tables to supply the required electric components of different kinds. On the other hand, the position of the component feeder on the other or non-operating table (auxiliary component supply table) which accommodates the electric components of the kind exhausted on the main component supply table varies depending upon the exhausted kind. Where the component feeder on the auxiliary component supply table which accommodates the electric components of the exhausted kind is comparatively near the end of the auxiliary component supply table on the side remote from the main component supply table, the distance of movement of the auxiliary component supply table required to supply the exhausted kind of electric components is comparatively large, and the overall component supplying efficiency is accordingly deteriorated. The method according to the above mode (9) is effective to minimize the deterioration of the component supplying efficiency. Described in greater detail, the third component-supplying step is implemented when each of the first and second tables has been exhausted of the electric components of at least one kind, and where the at least one kind exhausted on the first table is different from the at least one kind exhausted on the second table. In the third component-supplying step, the electric components of the at least one kind exhausted on one of the two tables are supplied from the other table (hereinafter referred to as “assisting component supply table”). The technical feature according to the above mode (9) relates to a manner of selection of one of the two tables as the auxiliary component supply table, in order to minimize the deterioration of the overall component supplying efficiency. Namely, the method according to the above mode (9) is arranged such that one of the first and second tables is used as the auxiliary component supply table to supply only the electric components of the at last one kind exhausted on the other table, while this other table is used as the main component supply table to supply the electric components of the at least one kind exhausted on the above-indicted one kind and different from the at least one kind exhausted on the other table, if the total distance of movements of the above-indicated one table required to supply the electric components of the at least one kind exhausted on the other table is smaller than the total distance of movements of the other table required to supply the electric components of the at least one kind exhausted on the above-indicated one table. This arrangement makes it possible to minimize the deterioration of the overall component supplying efficiency in the third component-supplying step.

(10) The method according to the above mode (8) or (9), wherein the third component-supplying step is implemented such that the first and second tables are moved in a same direction at a same speed in at least a portion of a movement of one of said first and second tables to supply the electric component, such that the first and second tables are held adjacent to each other during movements thereof.

The first and second tables may be moved together in synchronization with each other while one of the two tables is moved to supply the electric components of the kind exhausted on the other table is moved to move the appropriate component feeder to the component supply position. Alternatively, the first and second tables may be moved together in at least a terminal portion of the movement of one of the two tables to supply the electric component of the kind exhausted on the other table. In the former case, the two tables are moved as if these two tables were a single table arranged to supply the necessary electric components, so that a device which receives the electric components from a component supplying device including the two tables is less likely to be influenced by a change of the component supply table used to supply the electric components. In the latter case, it is possible to reduce the time period during which the two tables are moved together, thereby permitting reduction of the magnitude of the vibration of the component supplying device and consequent deterioration of the positioning accuracy of the component feeders, which magnitude is relatively large where the two tables are moved together, that is, where a portion of the component supplying device, which portion is moved to supply the electric component, has a relatively large mass. If the non-operating table located at its standby position is re-loaded with the electric components of the kind which has been exhausted, it is possible to reduce a need of interrupting the supply of the electric components from the two tables due to exhaustion of the electric components of the same kind on the two tables. If all of the component feeders exhausted on the non-operating table can be re-loaded with the electric components of the respective kinds, the component supplying operation can be returned from the third component-supplying step back to the second component-supplying step. In this case, the overall component supplying efficiency can be further

(11) The method according to any one of the above modes (1)-(10), further comprising a re-loading step in which at least one exhausted feeder if included in the plurality of component feeders of one of the first and second tables which is held in the off state is re-loaded with the electric components of the corresponding at least one kind.

(12) The method according to the above mode (11), wherein when all of the at least one exhausted feeder of the first table held in the off state have been re-loaded with the electric components in the second component-supplying step, this second component-supplying step is treated as the first component-supplying step in a subsequent control of operations of the two component supply tables.

In the second component-supplying step which is now treated as the first component-supplying step, the two tables which have functioned as the first and second tables now function as the second and first tables, respectively.

(13) A method of mounting electric components on a printed board, the method comprising supplying an electric-component mounting device with the electric components according to a method defined in any one of the above modes (1)-(12).

The printed board may be any one of a printed-wiring board which is a substrate with a printed circuit on which no electric components are mounted; a printed-wiring board on which electric components are provisionally fixed with an adhesive agent or a solder paste; and a printed-circuit board wherein some of electric components to be eventually mounted on the board are electrically connected to the printed circuit.

The component mounting method according to the above mode (13) assures a reduced amount of deterioration of efficiency of mounting of the electric components on the printed board, which may take place due to interruption of an operation to supply the electric-component mounting device with the necessary electric components.

(14) A component supplying device comprising:

two component supply tables each including a feeder support structure and a plurality of component feeders mounted on the feeder support structure, each of the plurality of component feeders accommodating a group of electric components of one kind and arranged to successively supply the electric components from a component-supply portion thereof, and

a component supply control device operable in control modes including at least: (a) a first control mode in which a first table which is one of the two component supply tables is operated to supply the electric components, while a second table which is the other of the two component supply tables is held in an off state; (b) a second control mode in which the first table is held in an off state while the second table is operated to supply the electric components, after the first table has been exhausted of the electric components of any kind; and (c) a third control mode in which the first and second tables cooperate to supply the electric components after the second table has been exhausted of the electric components of any kind.

Each of the two component supply tables may be arranged to be movable by a table moving device, in a direction in which the component-supply portion of the plurality of component feeders are arranged on the feeder support structure. In operation, each component supply table is moved to move a selected one of the component feeders to a predetermined component supply position. Alternatively, the two component supply tables may be fixedly disposed. Whether the two component supply tables are either movable or stationary is determined depending upon the specific arrangement of a device which receives the electric component from the component supplying device, as described below with respect to the following mode (15).

The first and second component supply tables may be disposed such that the component-supply portions of the plurality of component feeders of the first table and those of the second table are arranged along a single line. Alternatively, the two tables may be disposed such that a line along which the component-supply portions of the component feeders of the first table are arranged and a line along which the component-supply portions of the component feeders of the second table are arranged are parallel to each other and are spaced apart from each other in a direction intersecting those two lines. In the latter case, the two lines may be located symmetrically with each other with respect to a predetermined line or plane of symmetry.

The line along which the component-supply portions the component feeders of each table are arranged may be either straight or curved (arcuate), or may be a combination of a straight line and a curved line.

The component supplying device according to the above mode (14) has substantially the same advantages as described above with respect to the component supplying method according to the above method (1). The technical feature of any one of the above modes (1)-(12) is applicable to the component supplying device according to the mode (14).

(15) A component mounting system comprising:

a component supplying device constructed according to the above mode (14);

a board supporting device arranged to hold a printed board; and

a component mounting device operable to receive the electric components from the component supplying device, and mount the electric components on the printed board supported by said board supporting device.

For instance, the component mounting device may be one of the following three types: (a) a device including a plurality of component holding devices, and a moving device in the form of a turning device operable to turn the plurality of component holding devices about a common axis of turning such that each of the component holding device is sequentially stopped at a plurality of working positions arranged along a circle having a center at the common axis of turning, so that the component holding device located at one of the working positions receives the electric component from the component supplying device, while the component holding device located another of the working positions transfers the electric component onto the printed board; (b) a device including a component holding device movable in a plane parallel to the component mounting surface of the printed board, in two mutually perpendicular directions, and a moving device operable to move the component holding device in the above-indicated plane, to desired positions at which the component holding device receives the electric components from the component supplying device, so that the electric component is transferred from the component holding device onto the printed board; and (c) a device including a component holding device movable in a plane parallel to the component mounting surface of the printed board, in one of two mutually perpendicular directions, and a moving device operable to move the component holding device in the above-indicated one direction, to receive the electric components from the component supplying device and mount the electric components onto the printed board.

In the component mounting system including the component mounting device of the type (a), the board supporting device includes a board supporting unit for supporting the printed board, and a board moving device operable to move the board supporting unit in the plane parallel to the printed board, in the two mutually perpendicular directions, while the component supplying device includes the two component supply tables, and a table moving device operable to move the component supply tables in a direction in which the component-supply portions of the plurality of component feeders of each table are arranged. In the component mounting system including the component mounting device of the type (b), the board supporting device and the component supply tables are fixedly disposed. In the component mounting system including the component mounting device of the type (c), the board supporting device includes a board supporting unit for supporting the printed board, and a board moving device operable to move the board supporting unit in the plane parallel to the printed board, in one of the two mutually perpendicular directions in which the component holding device is not movable. In this third case, the component supply tables may be fixedly disposed such that the component holding device is movable to each of the component-supply portions of the component feeders. Alternatively, the component supply tables may be movable in the direction in which the component-supply portions of the component feeders are arranged.

Where the component holding device is movable by the moving device in the plane parallel to the printed board or along a straight line in this plane, another moving device may be provided to give the component holding device a supplemental or auxiliary motion. Where a plurality of component holding devices are carried by a rotary body (e.g., intermittently rotated indexing body), for instance, this rotary body may be arranged to be linearly movable by another moving device in two mutually perpendicular directions in the above-indicated plane, so that each component holding head is moved to a desired component mounting spot on the printed board, by a combination of the rotary and linear motions of the rotary body. In this case, the axis of rotation of the rotary body may be either perpendicular or inclined to the plane in which the component holding devices are linear moved. The working position at which each component holding device carried by the rotary body receives the electric component from the component supplying device may be the same as or different from the working position at which each component holding device transfers the electric component onto the printed board.

(16) The component mounting system according to the above mode (15), wherein the component mounting device comprises:

a plurality of component holding device operable to hold the electric components; and

a turning device operable to turn the plurality of component holding devices about a common axis of turning, such that each of the component holding devices is sequentially stopped at at least a predetermined component-receiving position at which each component holding device receives the electric components from the component supplying device, and a predetermined component-mounting position at which each component holding device transfers the electric components onto the printed board supported by the board supporting device.

Each of the component holding devices includes a component holder for holding the electric component. The component holder may be a suction nozzle arranged to hold the electric component by suction under a reduced pressure, or a gripper which consists of a plurality of gripper members in the form of jaws that are radially inwardly and outwardly movable to hold and release the electric component. The component holding device may be considered to include both a component holder, and a holder-supporting member arranged to removably hold the component holder. Alternatively, the component holding device may be considered to include the holder-supporting member arranged to hold the component holder, which is not a part of the component holding device. Further alternatively, the component holding device may be considered to consist of only the component holder.

The turning device may include a rotary body rotatable about an axis, and a rotating device operable to rotate the rotary body in a selected one of opposite directions by a desired angle. The rotary body carries the plurality of component holding devices, and is rotated to move each component holding device sequentially to the component-receiving position and the component-mounting position. The rotary body may be an rotated indexing body which is intermittently rotated by an intermittently rotating device and which carries the component holding devices such that the component holding devices are equiangularly spaced apart from each other in the rotating direction of the indexing body. In this case, each component holding device is sequentially stopped at the component-receiving and component-mounting positions by intermittent rotary motions of the indexing body. Alternatively, the turning device may include a plurality of rotary members arranged about a common axis of turning such that the rotary members can be turned about the common axis of turning, and a turning-motion applying device including a cam device operable to turn the rotary members about the common axis, at a speed controlled in a predetermined pattern, so that each rotary member is sequentially stopped at a plurality of working stations at different times. The rotary members carry the respective component holding devices such that each component holding device is rotatable about its axis and is axially movable relative to the rotary members, so that the component holding devices can be turned with the rotary members about the common axis of turning.

### BRIEF DESCRIPTION OF THE DRAWINGS

The above and other objects, features, advantages and technical and industrial significance of the present invention will be better understood by reading the following detailed description of presently preferred embodiments of the invention, when considered in connection with the accompanying drawings, in which:

FIG. 1 is a perspective view showing an external overall appearance of an electronic-component mounting system constructed according to one embodiment of this invention;

FIG. 2 is a front elevational view partly in cross section of the electronic-component mounting system of FIG. 1;

FIG. 3 is a plan view schematically showing an electronic-component supplying device used in the electric-component mounting system;

FIG. 4 is a side elevational view showing one of tape feeders of a component supply table provided in the electronic-component mounting system;

FIG. 5 is a plan view illustrating a portion of a carrier tape set in the tape feeder of FIG. 4;

FIG. 6 is a view for explaining working positions at which component holding heads of an electronic-component mounting device in the electronic-component mounting system;

FIG. 7 is a block diagram showing various elements of a control device of the electronic-component mounting system, which relate to the present invention;

FIGS. 8A-8C are views for explaining a component-mounting operation of the electronic-component mounting device to mount electronic components;

FIG. 9 is a view showing the positions of first and second component supply tables of the electric-component supplying device before initiating the component mounting operation in a cooperative same-board table changing mode;

FIG. 10 is a view for explaining a component-supplying operation of the first component supply table to supply the electronic components;

FIGS. 11A-11D are views for explaining a component-supplying operation of the electric-component supplying device when one of the tape feeders of the first component supply table has been exhausted;

FIGS. 12A-12B are views for explaining a case where some of the tape feeders of the first component supply table have been exhausted;

FIG. 13 is a view for explaining a component-supplying operation of the second component supply table;

FIGS. 14A and 14B are views for explaining a case where the first and second component supply tables cooperate to perform the component-supplying operation when some of the tape feeders of the second component supply table have been exhausted;

FIGS. 15A and 15B are views for explaining a case where another tape feeder of the first component supply table has been exhausted during the cooperative component-supplying operation of the first and second component supply tables;

FIG. 16 is a view for explaining a case where the tape feeders for the same kinds of electronic components have been exhausted in both of the first and second component supply tables;

FIG. 17 is a view for explaining a state in which the component-mounting operation is interrupted where the tape feeders for the same kinds of electronic components have been exhausted in the first and second component supply tables;

FIG. 18 is a view for explaining a change of the kind of an electronic component to be held by one of twelve component mounting heads, and a shift of assignment of the other heads to hold the respective kinds of electronic components, where one of the heads has failed to hold the electronic component of a given kind;

FIG. 19 is a view for explaining the above-indicated change and shift of assignment, where the above-indicated one component mounting head has also failed to hold the electronic component of the same kind;

FIG. 20 is a view schematically illustrating a portion of a RAM of the control device which relates to another of the invention;

FIG. 21 is a view for explaining an operating state of main and auxiliary component supply tables of an electric-component supplying device in an electronic-component mounting system according to a further embodiment of this invention, when the component-mounting operation is performed in the cooperative same-board table changing mode;

FIG. 22 is a view for explaining another operating state of the main and auxiliary component supply tables in the cooperative same-board table changing mode in the embodiment of FIG. 21;

FIG. 23 is a view for explaining a further operating state of the main and auxiliary component supply tables in the cooperative same-board table changing mode in the embodiment of FIG. 21;

FIG. 24 is a plan view schematically showing an electronic-component mounting system according to a still further embodiment of this invention;

FIG. 25 is a side elevational view showing a component-mounting device in the electronic-component mounting system of FIG. 24; and

FIG. 26 is a block diagram showing various elements of a control device of the electronic-component mounting system of FIG. 24, which relate to the present invention.

### DETAILED DESCRIPTION OF THE PREFERRED EMBODIMENTS

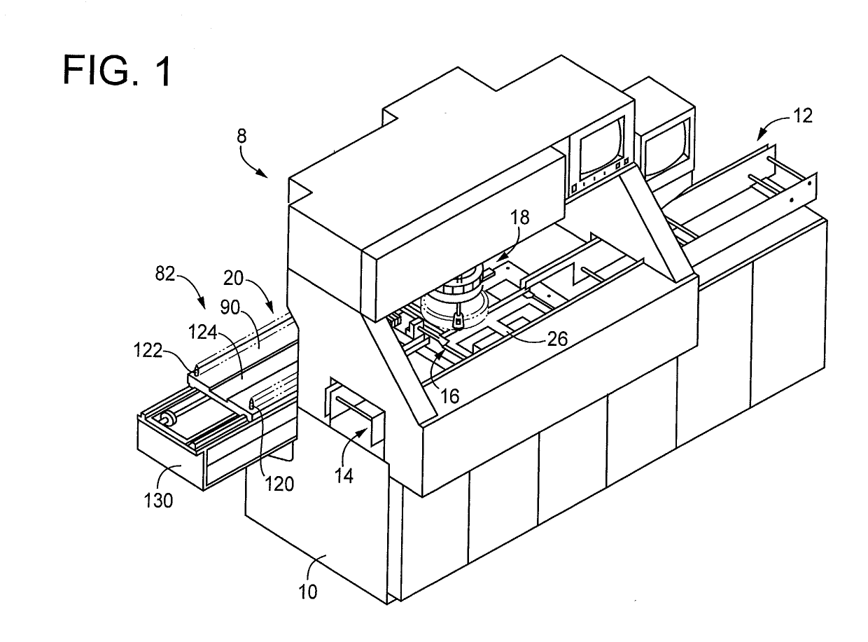

Referring first to FIG. 1, there is shown an external overall appearance of an electronic-component mounting system 8 constructed according to one embodiment of the present invention. The electronic-component mounting system 8 includes a main body frame 10, a board loading device in the form of a printed-wiring-board loading device 12 (hereinafter referred to as “PWB loading device 12), a board unloading device in the form of a printed-wiring-board unloading device 14 (hereinafter referred to as “PWB unloading device 14”), a board supporting device in the form of a printed-wiring-board supporting device 16 (hereinafter referred to as “PWB supporting device 16”), an electric-component mounting device in the form of an electronic-component mounting device 18 (hereinafter referred to as “component mounting device 18”) and an electric-component supplying device in the form of an electronic-component supplying device 20 (hereinafter referred to as “component supplying device 20”).

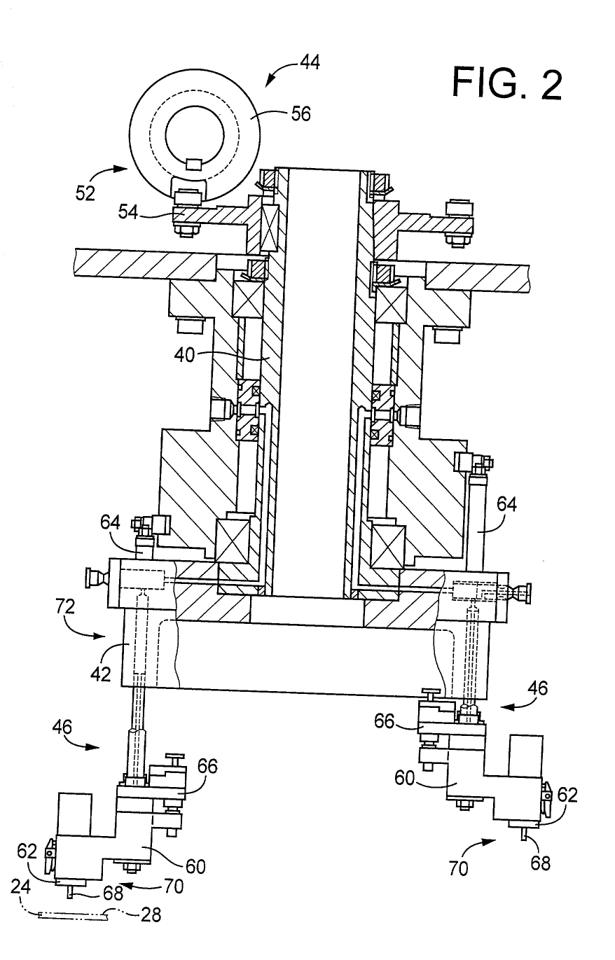

The PWB supporting device 16 is constructed as disclosed in JP-B2-2-49560, and a detailed description of this PWB supporting device 16 is not necessary for the understanding of the present invention. Accordingly, the PWB supporting device 16 will be only briefly described. The PWB supporting device 16 includes a board positioning device or a board-supporting-unit positioning device in the form of a PWB positioning device (not shown) or a PWB-supporting-unit positioning device (not shown), and a board supporting unit in the form of a printed-wiring-board supporting unit 26 (hereinafter referred to as “PWB supporting unit 26”) by the PWB positioning device. The PWB positioning device includes; an X-axis slide (not shown) movable in an X-axis direction in which a printed board in the form of a printed-wiring board 24 (FIG. 2) is moved by the PWB loading device 12 and the PWB unloading device 12; and a Y-axis slide mounted on the X-axis slide such that the Y-axis slide is movable in a Y-axis direction perpendicular to the X-axis direction. The PWB supporting unit 26, which is provided to support the printed-wiring board 24, is disposed on the Y-axis slide such that the PWB supporting unit 26 is movable in a Z-axis direction perpendicular to the X-axis and Y-axis directions. In the present embodiment, the printed-wiring board 24 is supported by the PWB supporting unit 26 such that the board 24 is held parallel to the horizontal plane. The printed-wiring board 24 thus supported by the PWB supporting unit 26 is moved to a desired position in an XY plane which is parallel to a surface 28 (FIG. 2) of the board 24 and which is defined by the X-axis and Y-axis directions. Namely, the X-axis and Y-axis directions are parallel to the horizontal plane, while the Z-axis direction is the vertical direction, and the XY plane is the horizontal plane.

The PWB loading device 12 and the PWB unloading device 14 are disposed on the respective opposite sides of the PWB supporting device 16, as seen in the X-axis direction, to load and unload the printed-wiring board 24 onto and from the PWB supporting device 16. The PWB supporting unit 26 of the PWB supporting device 16 is movable between an elevated position and a lowered position. In the elevated position, the PWB supporting unit 26 is able to receive the printed-wiring board 26 from the PWB loading device 12, and transfer the board 26 to the PWB unloading device 14. In the lowered position, the PWB supporting unit 26 is movable, without an interference with the PWB loading and unloading devices 12, 14, in the X-axis and Y-axis directions, so that a plurality of mounting spots on the printed-wiring board 26 at which electronic components are to be mounted are sequentially brought into a component-mounting position G (FIG. 6) of the component mounting device 18, that is, into a position right under a suction nozzle 62 of a component holding head 70 located at the component-mounting position G, as described below in detail.

The component mounting device 18 is constructed as disclosed in JP-B2-7-36480, and major elements of the component mounting device 18 will be described by reference to FIG. 2. This component mounting device 18 includes a rotary shaft 40, a rotary body in the form of an indexing body 42 fixed to a lower end portion of the rotary shaft 40, an intermittently rotating device 44 operable to rotate the indexing body 42, and twelve component mounting units 46 mounted on the indexing body 42. The rotary shaft 40 is supported by the main body frame 10 such that the rotary shaft 40 is rotatable about a vertically extending axis.

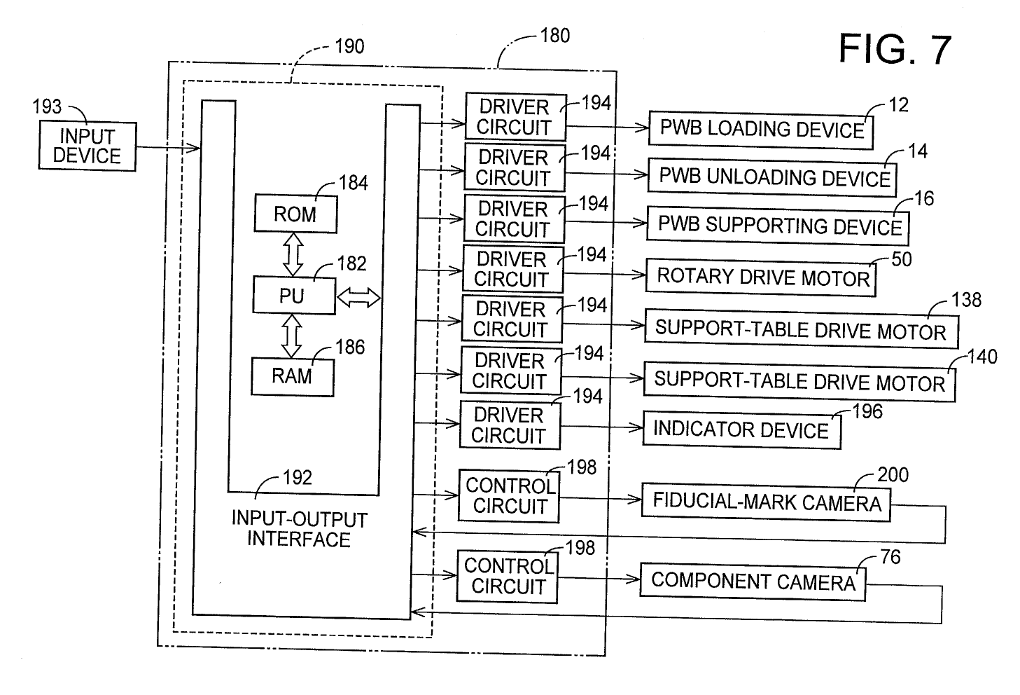

The intermittently rotating device 44 includes a drive power source in the form of a rotary drive motor 50 (FIG. 7), and a rotation transmitting device 52. In the present embodiment, the rotation transmitting device 52 includes a roller gear 54 and a roller gear cam 56. A continuous rotary motion of the rotary drive motor 50 is converted by the rotation transmitting device 52 into an intermittent rotary motion of the rotary shaft 40, so that the indexing body 42 is intermittently rotated.

The twelve component mounting units 46 are disposed on the indexing body 42 such that the units 46 are equiangularly spaced from each other along a circle which has a center on the axis of rotation of the indexing body 42. Each of the component mounting units 46 is arranged to perform various working operations such as an operation to receive the electronic component from the component supplying device 20, and an operation to mount the electronic component on the printed-wiring board 24. Each component mounting unit 46 includes a nozzle holder 60, and two suction nozzles 62 held by the nozzle holder 60.

The nozzle holder 50 is connected to the indexing body 42 through a rod 64 and a connecting member 66, such that the nozzle holder 50 is rotatable about a vertically extending axis parallel to the axis of rotation of the indexing body 42. Each of the two suction nozzles 62 is supported by the nozzle holder 60 such that the suction nozzle 62 extends in the vertical direction and is rotatable about its axis and axially movable relative to the nozzle holder 60. The two suction nozzles 62 are selectively placed in an operating position by a pivotal movement of the nozzle holder 60. The suction nozzle 62 placed in the operating position is provided with a negative pressure to hold the electronic component at the end of a suction tube 68. In the present embodiment, the suction nozzle 62 placed in the operating position and a portion of the nozzle holder 60 which holds that suction nozzle 62 are considered to constitute a component holding device in the form of the component holding head 70. The component mounting device 18 has a plurality of component holding heads 70, that is, twelve component holding heads 70 in the present embodiment. The portions of the twelve nozzle holders 60 which hold the suction nozzles 62 placed in the operating position may be considered to constitute the component holding heads. Alternatively, each of the two suction nozzles 62 of each nozzle holder 60 may be considered to constitute a component holding head, that is, the suction nozzles 62 of the twelve nozzle holders 60 may be considered to provide 24 component holding heads, with each component holding unit 46 having two component holding heads. For easier explanation, it is assumed that the two suction nozzles 62 of each of the twelve component holding units 46 (nozzle holders 60) are different in kind from each other, and that all of the twelve component holding units 46 have the same combination of the two suction nozzles 62.

When the indexing body 42 is intermittently rotated, the twelve component holding heads 70 are turned about a common axis of turning, that is, about the axis of rotation of the indexing body 42, such that each component holding head 70 is stopped at twelve working stations or positions A-L as sown in FIG. 6. In the present embodiment, the indexing body 42 and the intermittently rotating device 44 cooperate to constitute a turning device 72 operable to turn the plurality of component holding heads 70 about the common axis of turning.

The twelve working positions indicated above include: a component-receiving position A (component-holding position or component-sucking position A) aligned with the component supply position of the component supplying device 20; a component-hold-position detecting position C; a component disposing position D; a component-hold-position rectifying position E; the above-indicated component-mounting position G corresponding to the PWB supporting device 16; and a suction-nozzle selecting position L.

At the component-receiving position A and the component-mounting position G, there are respectively disposed respective pusher devices (not shown) operable to lower the selected suction nozzle 62 in the operating position to respective positions at which the selected suction nozzle 62 receives the electronic component from the component supplying device 20 and transfer the electronic component onto the printed-wiring board 24. In the present embodiment, each of these pusher devices utilizes the rotary drive motor 50 as its drive power source. The selected suction nozzle 62 which has been lowered by the pusher device is elevated to the original position under a biasing action of a spring (not shown) used as biasing means. The suction tube 68 of the selected suction nozzle 62 is selectively communicated with a negative-pressure source (not shown) and the atmosphere, through a switching device (not shown), so that the negative pressure is applied to the suction tube 68 for holding the electronic component, and the atmospheric pressure is applied to the suction tube 68 to release the electronic component. A positive pressure rather than the atmospheric pressure may be applied to the suction tube 68, for facilitating the removal of the electronic component from the suction tube 68.

At the component-hold-position detecting position C, there is disposed an imaging device in the form of a component camera 76 (FIG. 7), which functions as a component-hold-position detecting device. In the present embodiment, the component camera 76 is a CCD camera, which is operable to take a two-dimensional image of an object, more precisely, a silhouette or projection image of the electronic component as held by the suction nozzle 62. When the image of the electronic component is taken, the electronic component is illuminated by a suitable illuminating device (not shown). The component camera 76 may be arranged to take a front image of the electronic component with a light reflected from the electronic component.

At the component-hold-position rectifying position E, there is disposed a component-hold-position rectifying device (not shown), which is arranged to rotate the selected suction nozzle 62 placed in the operating position, about its axis, for rectifying an angular position of the electronic component about the axis of the suction nozzle 62, that is, for compensating the angular position of the electronic component for an angular positioning error. At the suction-nozzle selecting position L, there is disposed a suction-nozzle selecting device (not shown) arranged to pivot the nozzle holder 60 about its axis, for placing a selected one of the two suction nozzles 62 in the operating position. At the component disposing position D, the electronic component held by the selected suction nozzle 62 is released when needed, so that the released electronic component is fed into a component disposing device.

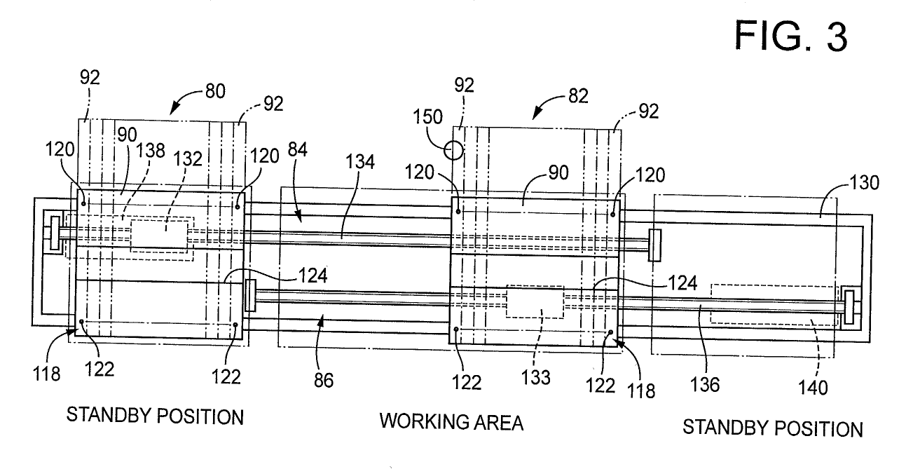

The component supplying device 20 will be described. As shown in FIG. 3, the component supplying device 20 includes a first component supply table 80, a second component supply table 82, a first table moving device 84 operable to move the first component supply table 80, and a second table moving device operable to move the second component supply table 82. Since the first and second component supply tables 80, 82 are identical in construction with each other, only the first component supply table 80 will be described by way of example.

The first component supply table 80 includes one feeder support structure in the form of a feeder carriage 90, and a plurality of tape feeders 92 mounted on the feeder carriage 90. These tape feeders 92 are positioned on the feeder carriage 90, by a tape feeder positioning device 118 which will be described.

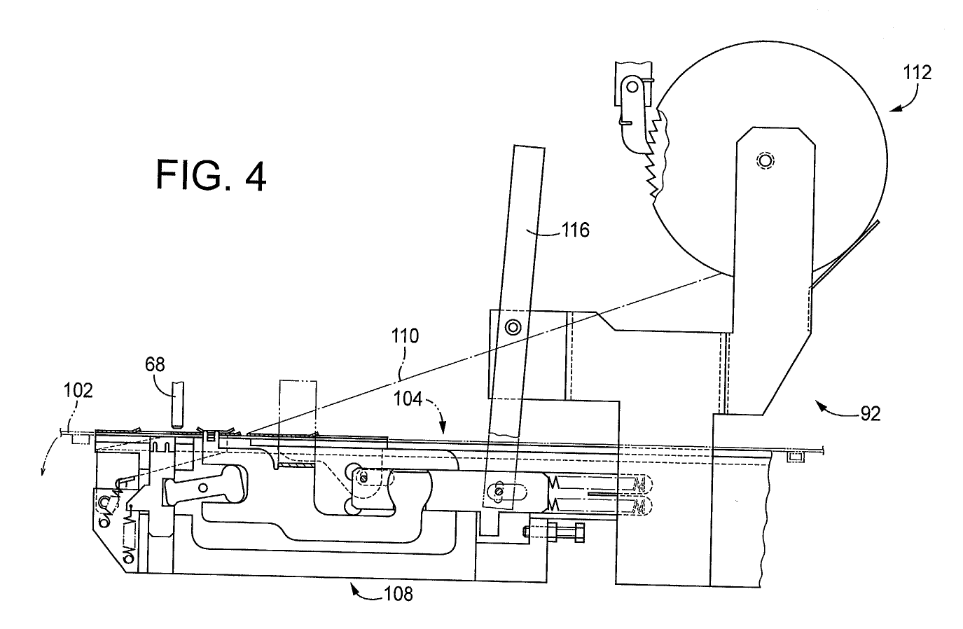

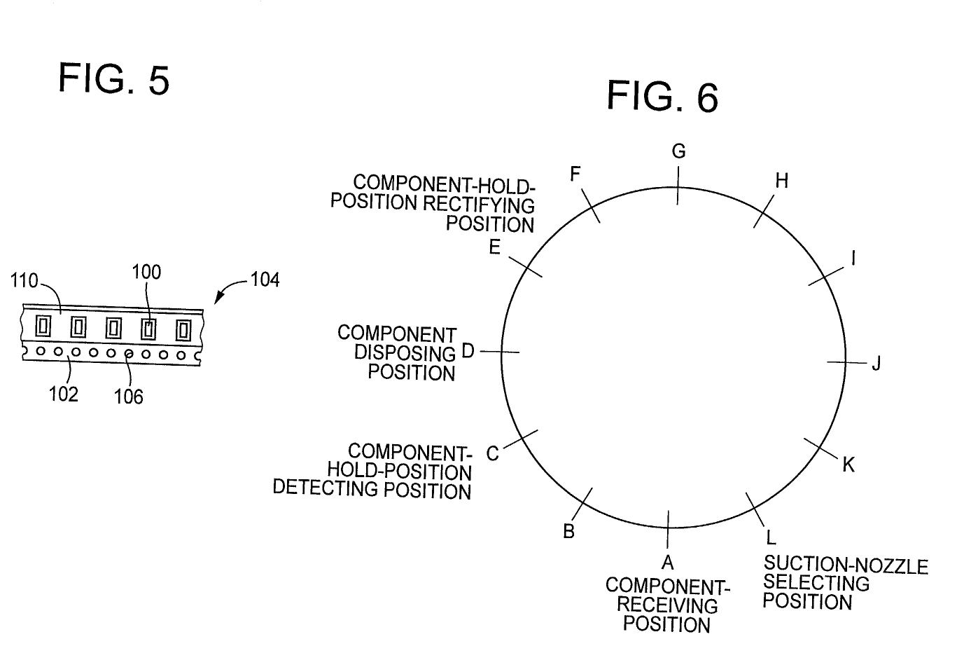

Each tape feeder 92 is constructed as disclosed in JP-B2-3-9640, and only major elements of the tape feeder 92 will be briefly described by reference to FIG. 4. Each tape feeder 92 is arranged to feed a carrier tape 104 which accommodates electric components in the form of electronic components 100, as shown in FIG. 5. The carrier tape 104 includes a carrier substrate 102 having a multiplicity of component-accommodating recesses formed at a suitable interval along the length of the tape. The electronic components 100 are accommodated in the respective recesses, and the opening of each recess is closed by a covering film 110 bonded to the surface of the carrier substrate 102 in which the recesses are open. The carrier substrate 102 has a multiplicity of feed holes 106 for feeding the carrier tape 104. The tape feeder 92 includes a feeding device 108 engageable with the feed holes 106, to feed the carrier tape 104 at a predetermined pitch. The tape feeder 82 further includes a take-up device 112 arranged to take up a length of the covering film 110 which has been removed from the carrier substrate 102.

The feeding device 108 utilizes the rotary drive motor 50 as its drive power source, and includes a rotation or motion transmitting device in the form of a cam device which includes a cam and a cam follower (not shown) and which is arranged to transmit a rotary motion of the rotary drive motor 50 to a drive member (not shown), so that a driven member is operated by the drive member, to feed the carrier tape 104 (carrier substrate 102). With each intermittent feeding movement of the carrier tape 104, the electronic component 100 accommodated in the foremost recess in the leading end portion of the carrier substrate 102 from which the covering film 110 has been removed is brought into a component supply position which is aligned with and located right below the suction tube 68 of the selected suction nozzle 62 of the component holding head 70 located at the component-receiving position A. The electronic component 100 thus located at the component supply position of the tape feeder 92 is held by the suction nozzle 62. The take-up device 112 also utilizes the rotary drive motor 50 as its drive power source, to take up the removed length of the covering film 110. Thus, the rotary drive motor 50 provided to rotate the indexing body 42 is utilized by both of the feeding device 108 and the take-up device 112, to feed the carrier tape 104 and take-up the covering film 119, in synchronization with the downward and upward movements of the suction nozzle 62 to pick up the electronic component 100.

The feeder carriage 90 used in the present embodiment takes the form of a plate as shown in FIG. 3, and is provided with the above-indicated tape feeder positioning device 118 to position the plurality of tape feeders 92. The tape feeder positioning device 118 includes a front array of positioning pins 120 and a rear array of positioning pins 122 fixed on the upper surface of the feeder carriage 90. The front and rear arrays are located at respective opposite ends of the feeder carriage 90 as seen in the direction of its width, that is, as seen in the direction perpendicular to the direction of movement of the feeder carriage 90. The front and rear arrays of positioning pins 120, 122 extend in the direction of length of the feeder carriage 90, that is, in the direction of movement of the feeder carriage 90 (i.e., in the X-axis direction). The tape feeder positioning device 118 further includes toggle clamp mechanisms fixed at respective grooves 124 which are formed in the upper surface of the feeder carriage 90 such that each groove 124 extends between each pair of the front and rear positioning pins 120, 122. The plurality of tape feeders 92 are positioned on the feeder carriage 90, by the respective pairs of front and rear positioning pins 120, 122, and are removably clamped such that the component supply positions or portions of the tape feeders 92 lie on a straight line parallel to the X-axis direction (right and left direction as seen in FIG. 3). It is noted that only some of the tape feeders 92 of each of the first and second component supply tables 80, 82 are shown in two-dot chain lines, in the interest of simplification, and that the tape feeders 92 are not shown in FIG. 1.

The number of different kinds of electronic components 100 to be mounted on the printed-wiring board 24, and the number of the electronic components 100 of each kind to be mounted on the board 24, depend upon the kind of the printed-wiring board 24. The size of the first and second component supply tables 80, 82, that is, the maximum number of the tape feeders 92 that can be mounted on each of the tables 80, 82, is determined depending upon various factors such as: the number of the different kinds of the electronic components 100 to be mounted on the printed-wiring board 24 of each one kind for which the component supply device 20 is intended to be used; the required numbers of the electronic components 100 of different kinds which are expected to be mounted; and the number of tape feeders 92 which accommodate the electronic components 100 of the same kind and which are expected to be mounted on one or both of the two tables 80, 82, in view of a need of supplying a relatively large number or numbers of electronic components 100 of the same kind or kinds.

The feeder carriage 90 of each of the first and second component supply tables 80, 82 is movably supported by a guide rail 130 which is disposed so as to extend in the X-axis direction in which the printed-wiring board 24 is moved by the PWB loading device 12 and PWB unloading device 14. That is, the two feeder carriages 90 are guided by the guide rail 130 such that the component supply portions of the plurality of tape feeders 92 are moved along a straight line parallel to the X-axis direction. The guide rails 130 is used commonly for the first and second component supply tables 80, 82, and is arranged to guide the feeder carriages 90 such that the straight line along which the component supply portions of the first component supply table 80 are arranged is aligned with the straight line along which the component supply portions of the second component supply table 82 are arranged.

As shown in FIG. 3, the two feeder carriages 90 have respective ballnuts 132, 133 fixed to their lower surfaces. These ballnuts 132, 133 are held in engagement with respective ballscrews 134, 136, which are supported by the guide rail 130 such that each ballscrew 134, 136 is rotatable about an axis parallel to the X-axis direction and is not axially movable. The ballscrews 134, 136 are rotated by respective drive power sources in the form of support-table drive motors 138, 140, to move the feeder carriages 90 of the first and second component supply tables 80, 82 in the X-axis direction (in the direction of arrangement of the tape feeders 92), independently of each other. The ballnut 132, ballscrew 134 and support-table drive motor 138 cooperate to constitute the first table moving device 84, while the ballnut 133, ballscrew 136 and support-table drive motor 140 cooperate to constitute the second table moving device 86.

The component supply position of the component supplying device 20 corresponds to a longitudinally middle portion of the guide rail 130, and is spaced a suitable distance from the ballscrew 134 in the Y-axis direction, as indicated by a circle 150 in FIG. 3. The electronic components 100 supplied from each tape feeder 90 are received by the suction tubes 68 when the tape feeder 90 is located at the component supply position 150. During an operation of the electronic-component mounting system 8, the tape feeders 80 are moved with the appropriate first or second component supply table 80, 82 such that the component supply portion of each tape feeder 80 is located at the component supply position 150 in which the component supply portion is right below the suction tube 68 of the selected suction nozzle 62 of the component holding head 70 located at the component-receiving position A.

A common component-supply area or working area in which the first and second component supply tables 80, 82 are moved to supply the electronic components 100 is defined by the above-indicated component supply position 150 and a maximum distance of movement of each table 80, 82 with respect to the component supply position 150, as indicated by one-dot chain line in FIG. 3. That is, the maximum distance of movement of each table 80, 82 is equal to a distance between the positions of the two tape feeders 92 mounted at the opposite ends of the table 80, 82, and the common working area is defined by the position of the tape feeder 92 at one of the opposite ends of each table 80, 82 when the tape feeder 92 at the other end of the table 80, 82 is located at the component supply position 150, and the position of the tape feeder 92 mounted at the above-indicated other end when the tape feeder 92 at the above-indicated one end is located at the component supply position 150. During a series of component mounting operation, the tape feeders 92 mounted on a selected one of the two component supply tables 80, 82 are continuously used with the selected table 80, 82 being moved within the common working area. Alternatively, the tape feeders 92 on the two tables 80, 82 are selectively used, with the desired tape feeders 92 on the appropriate one of the tables 80, 82 being moved to the component supply position 150. In the former case wherein one of the two component supply tables 80, 82 is located within the common working area, the other table 80, 82 is held at the corresponding one of two standby positions on the guide rail 130, which are spaced apart from the respective opposite ends of the working area in the longitudinal direction of the guide rail 130, so as to prevent an interference of the above-indicted other table 80, 82 with the above-indicated one table 80, 82 in the working area. These two standby positions, which are also indicated in one-dot chain lines in FIG. 3, are provided exclusively for the respective first and second component supply tables 80, 82 to be prepared for supplying the electronic components 100 when needed. The guide rail 130 has a length sufficient to permit the two component supply tables 80, 82 to be moved between the working area and their standby positions. The guide rail 130 functions as a guiding device for guiding the movements of the component supply tables 80, 82.

The present electronic-component mounting system 8 includes a control device 180 as indicated in the block diagram of FIG. 7. The control device 180 is principally constituted by a computer 190 incorporating a PU (processing unit) 182, a ROM (read-only memory) 184, a RAM (random-access memory) 186, and a bus interconnecting those elements 182, 184, 185. To the bus, there is connected an input-output interface 192 to which are connected an input device 193 and various sensors (not shown) which are used for mounting the electronic components 100 on the printed-wiring board 24. The input device 193 has ten digit keys, function keys, alphabet keys, etc. used for data entry by the operator.

To the input-output interface 192, there are also connected through driver circuits 194 various actuators such as the rotary drive motor 50, and an indicator device 196. In the present embodiment, the indicator device 196 includes an alarm device and a display device. Each of the drive power sources such as the rotary drive motor 50 is a servomotor, which is an electric rotary motor and the operating angle of which can be controlled with a comparatively high degree of accuracy. However, the servomotor may be replaced by a stepping motor. Each of the motors such as the rotary drive motor 50 is provided with a rotary encoder to detect its operating angle.

To the input-output interface 192, there are also connected through control circuits 198 the above-indicated component camera 76 and a fiducial-mark camera 200. The fiducial-mark camera 200 is used to take images of a plurality of fiducial marks (not shown), for example, two fiducial marks provided on the surface 28 of the printed-wiring board 24. The fiducial-mark camera 200 is fixedly disposed on the frame 10. Like the component camera 76 described above, the fiducial-mark camera 200 is a CCD camera capable of taking a two-dimensional image. The control circuits 198 and the driver circuits 194 cooperate with the computer 190 to constitute the control device 180. The RAM 186 stores various control programs such as programs for controlling operations of the electronic-component mounting system 8 in four different component-mounting modes to mount the electronic components 100 on the printed-wiring board 24, and various kinds of data necessary to execute those control programs.

The four component-mounting modes consist of: a cooperative table changing mode; a different-boards table changing mode; a non-cooperative same-board table changing mode; and a cooperative same-board table changing mode. The cooperative table changing mode is selected where the number of the kinds of the electronic components 100 to be mounted on the printed-wiring board 24 of a specific kind is relatively large, or where the number of the electronic components 100 to be mounted on the board 24 is relatively large. That is, the cooperative table changing mode is used where the tape feeders 90 on only one of the first and second component supply tables 80, 82 are not sufficient to supply the required number of the electronic components 100 of all of the different kinds to be mounted on the board 24 of the specific kind, so that the tape feeders 92 on both of the two tables 80, 82 are required to cooperate with each other to supply the necessary electronic components 100. In the cooperative table changing, the first and second component supply tables 80, 82 cooperate to supply the electronic components 100, such that the two tables 80, 82 are selectively moved into the common working area, so as to supply the electronic components 100 in a predetermined order on the board 24 as if the two tables 80, 82 were a single component supply device. In the cooperative table changing mode, the two tables 80, 82 are simultaneously moved to and from the component supply position 150, in order to speed up the switching between the two tables 80, 82.

The different-boards table changing mode is selected where the number of the kinds of the electronic components 100 to be mounted on each of the printed-wiring boards 24 of different kinds, and the number of the electronic components 100 to be mounted on each board 24, are not so large, so that the tape feeders 92 that can be mounted on one of the two component supply tables 80, 82 are sufficient to supply the necessary electronic components 100, but where the kind of the printed-wiring board 24 on which the electronic components 100 are to be mounted is expected to be relatively frequently changed. In this different-boards table changing mode, one of the two tables 80, 82 is operated in the working area for the board 24 of one kind, while the other table 80, 82 located at its standby position is prepared for the board 24 of another kind on which the electronic components 100 are expected to be mounted next. During the operation of the table in the working area, a set of tape feeders 92 suitable for the next type of the board 24 is set up on the other table at the standby position, by the operator. The table thus prepared for the next type of the board is moved from the standby position into the working area as soon as the electronic components 100 have been mounted on a predetermined number of the boards 24 of the present type, so that the operation to mount the electronic components 100 on the boards 24 of the next type is initiated.

The non-cooperative same-board table changing mode is selected where the number of the kinds of the electronic components 100 to be mounted on the printed-wiring board 24 of a specific kind, and the number of the electronic components 100 to be mounted on each board 24, are not so large, so that the tape feeders 92 necessary to mount the electronic components 100 on the board 24 can be mounted on only one or each one of the two tables 80, 82. In this non-cooperative same-board table changing mode, the two tables 80, 82 are equipped with same sets of tape feeders 92. Namely, the number of the tape feeders 92 mounted on one of the two tables 80, 82 and the kinds of the electronic components 100 accommodated in these tape feeders 92 are the same as the number of the tape feeders 92 mounted on the other table 80, 82 and the kinds of the electronic components 100 accommodated in these tape feeders 92. Further, the tape feeders 92 are arranged in the same order on the two tables 80, 82. The predetermined order of arrangement of the tape feeders 92 may be the same as or different from the order in which the electronic components 100 are mounted on the printed-wiring board 24. In the present embodiment, the tape feeders 92 are arranged on each table 80, 82 in the order in which the electronic components 100 are mounted.

In the non-cooperative same-board table changing mode, one of the two component supply tables 80, 82 is moved into the common working area and is operated as an operating or component-supply table to supply the electronic components 100, while the other component supply table 80, 82 is located at its standby position, as a non-operating or standby table or a spare table. The standby table at the standby position is prepared for the next use, by replacement of the exhausted tape feeders with the new ones. When any one of the tape feeders 92 on the operating table has been exhausted, this table is moved to its standby position and is held there as the non-operating or standby table, and the non-operating or standby table which has been held at the standby position is moved into the working area and is used as the operating or component-supply table to supply the electronic components 100. The tape feeder 92 which has been exhausted is interpreted to mean the tape feeder from which all of the electronic components 100 have been supplied to be mounted on the board 24. The tape feeder on the non-operating table, which has been exhausted, is replenished or re-loaded with the corresponding components 100. This replenishment or re-loading is effected, for instance, by removing the tape feeder 92 from the feeder carriage 90, removing the covering film 110 from the reel of the take-up device 112, installing a new reel carrying a roll of the carrier tape 104 on the main body of the removed tape feeder 92, feeding the carrier tape 104 a suitable distance by operation of the feeding device 108, and connecting the leading end portion of the covering film 110 to the reel of the take-up device 112. Alternatively, the removed tape feeder 92 as a whole is replaced by the new one, or the new carrier tape 104 is spliced to the trailing end of the old carrier tape 104 set in the removed tape feeder 92. The re-loading or replacement of the tape feeder 92 at the standby position is conducted by the operator or user of the system 8.

In the non-cooperative same-board table changing mode, the operating table 80, 82 any tape feeder 92 of which has been exhausted is replaced by the non-operating or standby table 80, 82 if the re-loading or replacement of the tape feeder or feeders 92 on the standby table has been completed. In this case, the table 80, 82 which has been held at the standby position is used as the operating table. If the re-loading or replacement on the standby table has not been completed when any tape feeder 92 on the operating table has been exhausted, the operation to mount the electronic components 100 is interrupted or suspended.

Like the non-cooperative same-board table changing mode, the cooperative same-board table changing mode is selected where the number of the kinds of the electronic components 100 to be mounted on the printed-wiring board 24 of a specific kind, and the number of the electronic components 100 to be mounted on each board 24, are not so large, so that the tape feeders 92 necessary to mount the electronic components 100 on the board 24 can be mounted on each of the two tables 80, 82. In this cooperative same-board table changing mode, too, the two tables 80, 82 are equipped with same sets of tape feeders 92, which are arranged in the predetermined order in which the electronic components 100 are mounted on the printed-wiring board 24. The cooperative same-board table changing mode is the same as the non-cooperative same-board table changing mode, also in that when any one of the tape feeders 92 on the operating table 80,82 in the working area has been exhausted, the non-operating table 80, 82 which has been held at the standby position is moved into the working area and operated as the operating table. However, the cooperative same-board table changing mode is different from the non-cooperative same-board table changing mode in that when any tape feeder 92 on the operating table 80, 82 which was moved into the working area and is now used as the operating table has been exhausted, a cooperative operation of the two tables 80, 82 is initiated to supply the necessary electronic components 100. In the cooperative same-board table changing mode, too, the re-loading or replacement of the tape feeder or feeders 92 is effected on the table 80, 82 which was first used as the operating table and is then held at the standby position. However, the cooperative operation of the two tables 80, 82 is initiated irrespective of whether the re-loading or replacement of the appropriate tape feeder or feeders 92 on the table at the standby position has been completed or not.

In the present electronic-component mounting system 8, a desired one of the four table changing modes is selected by the operator through a suitable selector switch (not shown) or the input device 193. Alternatively, the desired table changing mode is automatically selected according to a signal sent from an external host computer, for example. The operation of the component mounting device 18 to mount the electronic components 100 on the printed-wiring board 24 is performed in the same manner, irrespective of the table changing mode selected from among the four modes. The operation of the component mounting device 28 is well known as disclosed in JP-B2-8-21791, and will be only briefly described.

The operation of the electronic-component mounting system 8 is initiated with an operation of the PWB loading device 12 to move the printed-wiring board 24 onto the PWB supporting device 16, and an operation of the PWB supporting unit 26 to position and hold the board 24. In this state, the fiducial-mark camera 200 is operated to take images of the fiducial marks (not shown) provided on the board 24, and positioning errors of the board 24 in the XY plane parallel to the surface 28 of the board 24 are obtained on the basis of the obtained image. Positioning errors ΔXP and ΔYP of each of the component mounting spots on the board 24 in the X-axis and Y-axis directions are calculated on the basis of the obtained positioning errors of the board 24.

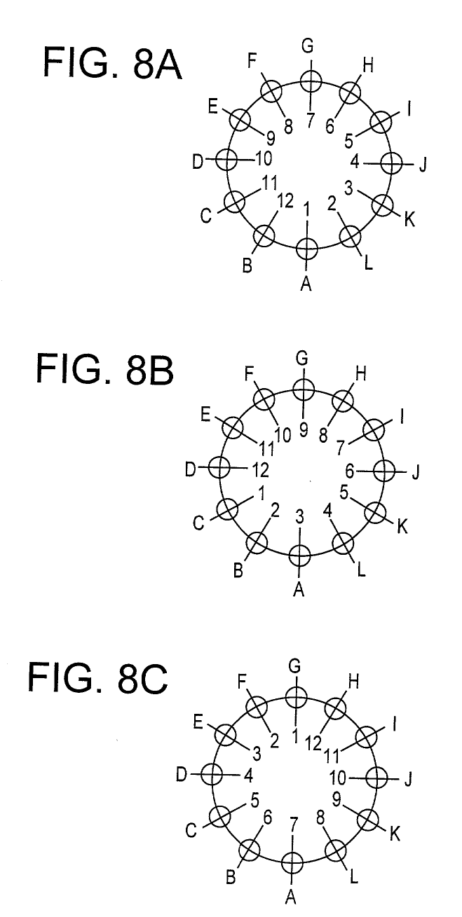

After the positioning errors ΔXP and ΔYP have been obtained, the operation of the component mounting device 18 to mount the electronic components 100 on the printed-wiring board 24 is initiated. To perform the component mounting operation, the indexing body 42 is intermittently rotated by the intermittently rotating device 44, so that each of the twelve component holding heads 70 is sequentially stopped at the component-receiving position A, the component-hold-position detecting position C, the component disposing position D, the component-hold-position rectifying position E, component-mounting position G, the suction-nozzle selecting position L, etc. The working operations by the twelve component holding heads 70 (which will be referred to as “first through twelfth component holding heads 70”, where appropriate) at the respective working positions take place substantially at the same time. The working operation of the first component holding head 70 at each of the twelve working positions will be briefly described by way of example, by reference to FIG. 8. In this figure, the first through twelfth component holding heads 70 are denoted by reference numerals 1-12, respectively.

To initiate an operation of the first component holding head 70 to receive the electronic component 100, the first head 70 located at the component-receiving position A as indicated in FIG. 8A is lowered, and the selected suction nozzle 62 is lowered to hold the electronic component 100 by suction under a reduced pressure. The first head 70 is then elevated to an upper position, and is moved to the working position B by the next rotary motion of the indexing body 42. In this working position B, no operation is performed by the first head 70. Then, the first head 70 is moved by the indexing body 42 to the component-hold-position detecting position C, as indicated in FIG. 8B. In this position C, the component camera 76 is operated to take the image of the electronic component 100 as held by the suction nozzle 62.

Data indicative of the image of the electronic component 100 are processed to check if the electronic component 100 is held by the suction nozzle 62, to check if the kind of the electronic component 100 held by the suction nozzle 62 is correct, and calculate positioning errors of the electronic component 100 as held by the suction nozzle 62. If the electronic component 100 is held by the suction nozzle 62, a determination as to whether the kind of the component 100 held by the suction nozzle 62 is correct or not is effected on the basis of an outer profile of the component 100 taken by the component camera 76. If the outer profile indicates that the kind of the component 100 is correct, the image data of the component 100 are compared with reference data indicative of an image of the component 100 to be taken when the component 100 is held by the suction nozzle 62 without any positioning errors. By this comparison of the image data with the reference data, the computer 190 obtain the positioning errors of the component 100, more precisely, center position errors ΔXE and ΔYE and an angular positioning error Δθ. The center position errors ΔXE and ΔYE are positioning errors of the center of the electronic component 100 with respect to the axis of the suction nozzle 62 in the X-axis and Y-axis directions in a plane perpendicular to the axis of the suction nozzle 62, while the angular position error Δθ is a positioning error of the component 100 in the circumferential direction of the suction nozzle 62 in the above-indicated plane.

When the image of the electronic component 100 held by the suction nozzle 62 on the first component holding head 70 is taken, the third component holding head 70 is located at the component-receiving position A, as indicated in FIG. 8B, to receive the electronic component 100. However, the operation of each head 70 at the component-receiving position A does not necessarily result in the actual holding of the electronic component 100 by the suction nozzle 62.

If it is detected that the kind of the electronic component 100 is different from that of the component 100 to be held by the first head 70, or the component 100 held by the first head 70 cannot or should not be mounted on the printed-wiring board 24, for any other reason, the electronic component 100 is released from the suction nozzle 62 of the first head 70 when the head 70 has been moved to the next component disposing position D, so that the component 100 is discarded onto the disposing device. Where the component 100 is discarded from the suction nozzle 62 of the first head 70 or is not actually held by the first head 70, the first head 70 is not operated at the component-mounting position G to mount the component 100 on the board 24.

Where it is detected at the component-hold-position detecting position C that the component 100 of the correct kind has been held by the first head 70, no operation of the first head 70 is performed at the component disposing position D, and the suction nozzle 62 is rotated to eliminate the angular positioning error Δθ of the component 100 when the first head 70 is located at the component-hold-position rectifying position E.

When the first head 70 has been moved to the component-mounting position G, as indicated in FIG. 8C, with a rotary motion of the indexing body 42, the suction nozzle 62 is lowered to mount the electronic component 100 onto the surface 28 of the printed-wiring board 24, by application of the atmospheric pressure to the suction nozzle 62 to release the component 100. To this end, the board 24 is moved with a movement of the PWB supporting unit 26 by the PWB positioning device (not shown), so that an appropriate mounting spot on the board 24 is located at the component-mounting position G. At this time, the distances of movement of the board 24 in the X-axis and Y-axis directions are compensated for the positioning errors ΔXP and ΔYP of the component mounting spot, the center positioning errors ΔXE and ΔYE of the electronic component 100, and horizontal positioning errors of the component 100 which are caused as a result of the angular position adjustment of the component 100 to eliminate the angular positioning error Δθ. Thus, the component 100 is mounted at the appropriate nominal mounting spot, with the nominal attitude and angular orientation.

As indicated in FIG. 8C, the seventh component holding head 70 is located at the component-receiving position A to receive the appropriate electronic component 100 from the component supplying device 20, when the first head 70 is operated at the component-mounting position G to mount the electronic component 100 onto the printed-wiring board 24. The first head 70 reaches the suction-nozzle selecting position L, with five more intermittent rotary motions of the indexing body 42. If the presently selected suction nozzle 62 is required to be replaced by the other suction nozzle 62, that is, if the other suction nozzle 62 is required to be placed in the operating position for holding the next electronic component 100, the nozzle holder 60 of the first head 70 is rotated by the suction-nozzle selecting device at the suction-nozzle selecting position L.

The operations of two component supply tables in the cooperative table changing, the different-boards table changing mode and the non-cooperative table changing mode which have been described are known, as disclosed in JP-B2-8-21791. No further description on these modes is deemed necessary. There will be described in detail the operation to mount the electronic components 100 on the printed-wiring board 24, in the cooperative same-board table changing mode.

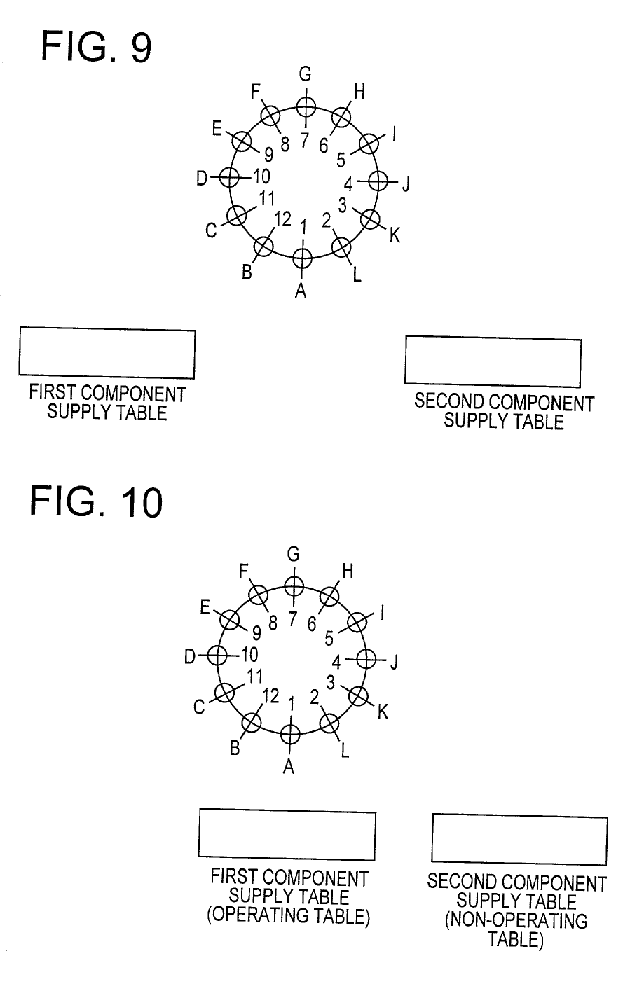

Before the component mounting operation in the cooperative same-board table changing mode is initiated, the first and second component supply tables 80, 82 are located at the respective standby positions, as indicated in FIG. 9. In this table changing mode, the same number of the tape feeders 92 accommodating the same kinds of electronic components 100 are mounted on each of the two tables 80, 82 (two feeder carriages 90), such that the tape feeders 92 are arranged in the predetermined order, that is, in the order in which the components 100 are sequentially mounted on the printed-wiring board 24, as described above. That is, the two tables 80, 82 are equipped with the same sets of tape feeders 62. Two or more tape feeders 92 accommodating the same kind of components 100 may be mounted on each of the tables 80, 82. In this case, these two or more tape feeders 92 are arranged adjacent to each other in the present embodiment. However, the adjacent arrangement of these tape feeders 92 is not essential. Thus, the component mounting operation includes a preparing step of preparing the two component supply tables 80, 82 which are equipped with respective sets of tape feeders 92 capable of supplying a same combination of electric components of different kinds.

The component mounting operation to mount the electronic components 100 on the printed-wiring board 24 is initiated with a movement of the first component supply table 80 to the working area, as indicated in FIG. 10, to mount the electronic components 100. The first component supply table 80 is moved by the first table moving device 84 in the direction in which the component supply portions of the tape feeders 92 are arranged on the first table 80. Described more specifically, the first table 80 is moved such that the tape feeders 92 are successively located at the component supply position 150, in the predetermined order in which the tape feeders 92 are arranged and in which the components 100 are supplied to be mounted on the board 24. In the meantime, the second component supply table 82 is held stationary and in the off state at its standby position. The table operated in the working area (first table 80 in this instance) is the operating table while the table held at the standby position (second table 82 in this instance) is the non-operating or standby table. The operation of the first table 80 in the working area to supply the electronic components 100 while the second table 82 is held at rest at the standby position is a first component-supplying step, which is controlled by the control device 180 in a first control mode.

When any one of the tape feeders 92 mounted on the first component supply table 80 has been exhausted of the electronic components 100 of a kind “a”, the electronic components 100 of this kind “a” are then supplied from any other tape feeder 92 accommodating the components 100 of the kind “a”, if such other tape feeder 92 is mounted on the first table 80.

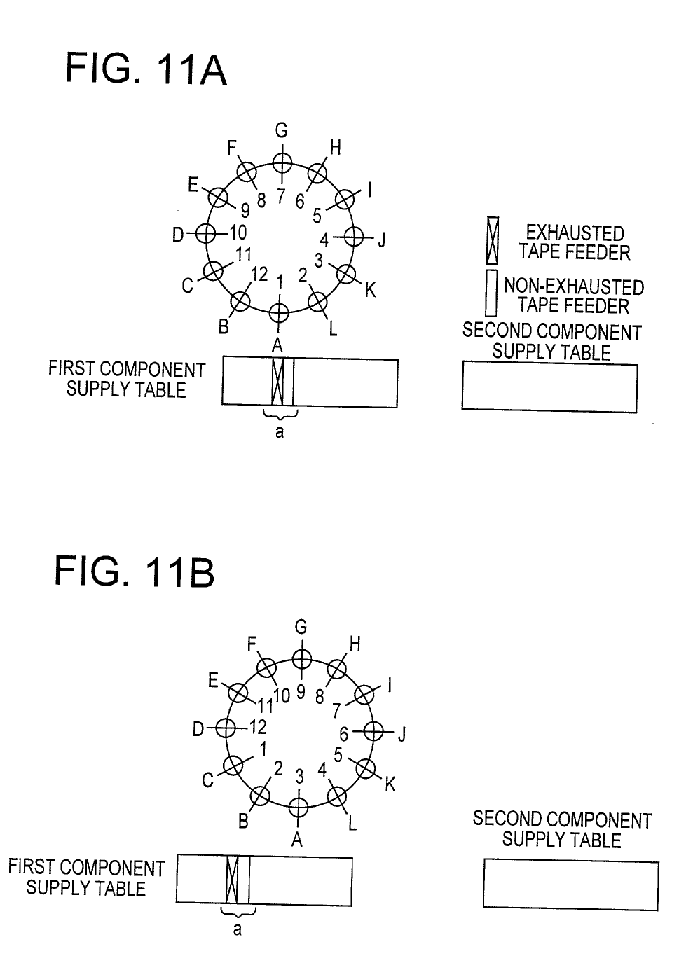

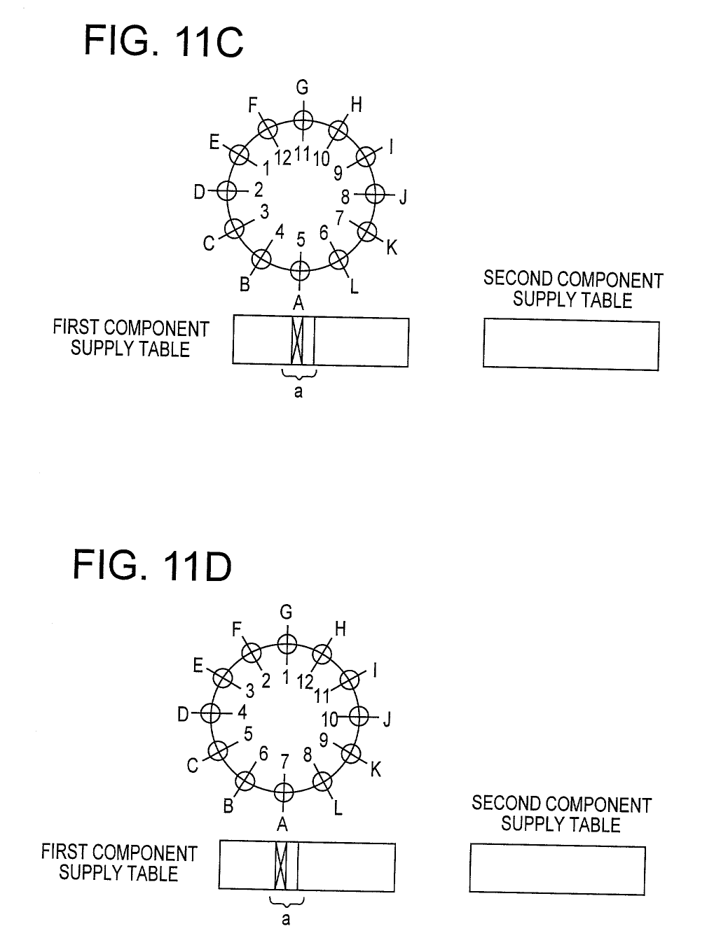

In the present embodiment, a decision that the tape feeder 92 in question has been exhausted or not is made if a failure of the heads 70 to receive the electronic component 100 from that tape feeder 92 is detected two consecutive times. In the example of FIG. 11A, the first head 70 is assigned to receive the component 100 of the kind “a” at the component-receiving position A. If the relevant tape feeder 92 has been exhausted of the electronic components 100 of the kind “a” so that the first head 70 has failed to receive the component 100 of the kind “a”, this failure is detected on the basis of image data obtained by the component camera 76 when the first head 70 is located at the component-hold-position detecting position C, as indicated in FIG. 11B.

In this event, it is possible to operate the first head 70 again at the component-receiving position A, to try to receive the component 100 of the kind “a” from the tape feeder 92 from which the first head 70 failed to receive that component 100. In the present embodiment, however, another head 70 other than the first head 70 is operated to try to receive the component 100 of the kind “a” at the position A, in order to mount the component 100 of this kind “a” as soon as possible. As described above, each of the twelve component mounting units 46 has the two suction nozzles 62 of different kinds, but all of the component mounting units 46 have the same set of two suction nozzles 62, so that all of the component mounting units 46 can hold the component 100 of the same kind. According to this arrangement, the component 100 of the kind “a” can be received by any one of the heads 70 other than the first head 70, in the event of a failure of the first head 70 to receive the component 100 of the kind “a”.

In the present embodiment, the fifth head 70, which is located at the working position K adjacent to the suction-nozzle selecting position L (as seen in the direction toward the component-mounting position G) when the first head 70 is located at the component-hold-position detecting position C, is operated at the component-receiving position C, to try to receive the component 100 of the kind “a”. When the first head 70 is located at the position C, the operations of the second and third heads 70 to receive the components 100 of the other kinds have been performed or in progress, while the fourth head 70 is located at the suction-nozzle selecting position L. If the kind of the suction nozzle 62 presently selected on the fourth head 70 is different from that of the suction nozzle 62 used to receive the component 100 of the kind “a”, the other suction nozzle 62 must be newly selected on the fourth head 70 at the suction-nozzle selecting position L. However, the fourth head 70 does not have a sufficient time to select the other suction nozzle 62.

In view of the above situation, one of the heads 70 which is located nearest to the component-receiving position A and which can receive the component 100 of the kind “a”, that is, the fifth head 70 located at the working position K adjacent to the suction-nozzle selecting position L as seen in the direction toward the component-mounting position C is operated at the component-receiving position A to try to receive the component 100 of the kind “a” from the tape feeder 92 from which the first head 70 failed to receive the component 100 in question.

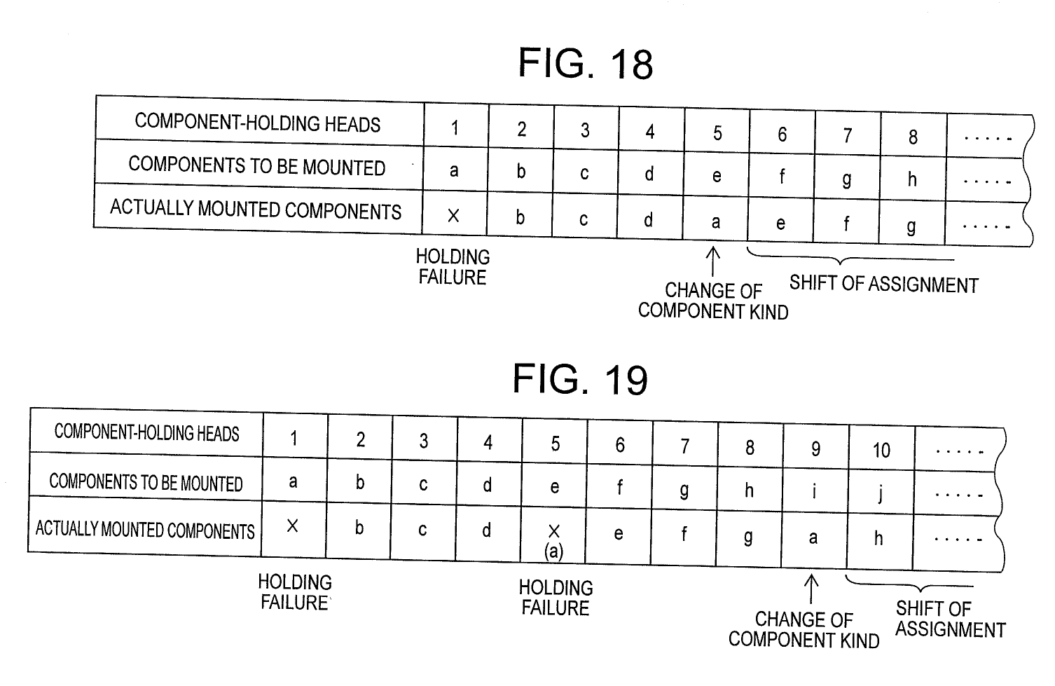

The fifth head 70 is assigned to receive and mount the electronic component 100 of a kind different from the kind “a” of the component 100 to be received by the first head 70. Namely, the fifth head 70 is assigned to receive the component 100 of the kind “e”. If the fifth head 70 is used in place of the first head 70, to hold the component 100 of the kind “a”, the operation of the fifth head 70 to hold the component 100 of the kind “a” takes place after the operation of the fourth head 70 to hold the component 100 of a kind “d”, and the assignment of the sixth and the following heads 70 to hold the components 100 of respective different kinds “e”, “f”, etc. must be shifted one position, as indicated in FIG. 18. Accordingly, the kind of the suction nozzle 62 used on each of the sixth and the following heads 70 must be shifted according to the shift of assignment of those heads 70 in terms of the kind of the components 100 to be held by the heads.

As described above, all of the twelve component mounting units 46 have the same set of two suction nozzles 62 of different kinds, so that the components 100 of all kinds to be mounted can be held by one or the other of the two suction nozzles 62 of any component mounting unit 46. Thus, the application of the individual component holding heads 70 is not limited to the specific kind of the component 100. Accordingly, the original assignment of the heads 70 to hold the respective kinds of the components 100 can be changed or shifted as needed, by selective use of the two suction nozzles 62 depending upon the kind of the component 100 to be held.

The kind of the suction nozzle 62 to be used to hold each electronic component 100 to be mounted at each of the mounting spots on the printed-wiring board 24 is determined by the kind of the component 100 to be mounted at each mounting spot. The components 100 are supplied from the component supplying device 20, in the predetermined order in which the components 100 are mounted on the printed-wiring board 24. In the event of a failure of a given one of the heads 70 to hold a given component 100, the first component supply table 80 is positioned such the tape feeder 92 accommodating the component 100 of the kind “a” which the first head 70 failed to receive is moved to the component supply position 150 when the fifth head 70 is moved to the component-receiving position C, as indicated in FIG. 11C. Thus, the predetermined order in which the components 100 of the different kinds are supplied from the component supplying device 20 is changed.

When the first head 70 which failed to receive the component 100 of the kind “a” has been moved to the component-mounting position G, this component 100 is not mounted on the corresponding mounting spot on the printed-wiring board 24 even when the board 24 is positioned bring this mounting spot into alignment with the component-mounting position G. In view of this fact, the printed-wiring board 24 need not be positioned for mounting the component 100 of the kind “a” by the first head 70. However, the board 24 may be positioned for the first head 70, even if the component 100 of the kind “a” is not mounted at the corresponding mounting spot on the board 24 by the first head 24. When the fifth head 70 holding the component 100 of the kind “a” is moved to the component-mounting position G, the board 24 is positioned to bring the appropriate mounting spot into alignment with the component-mounting position G, so that the component 100 of the kind “a” is mounted at that mounting spot by the fifth head 70. Thus, the predetermined order in which the components 100 of the different kinds are mounted on the printed-wiring board 24 is also changed.

If image data obtained when the fifth head 70 has been moved to the component-hold-position detecting position C indicate that the component 100 of the kind “a” is held by the fifth head 70, this means that the relevant tape feeder 92 has not been exhausted of the components 100 of the kind “a”, but the first head 70 failed to hold the component 100 of the kind “a”, for some other reason.

If the image data indicate that the component 100 of the kind “a” is not held by the fifth head 70, this means that the relevant tape feeder 92 on the first table 80 has been exhausted of the components 100 of the kind “a”. If, in this case, the first table 80 has any other tape feeder 92 accommodating the components 100 of the kind “a”, the first table 80 is positioned to move this tape feeder 92 to the component supply position 150, for supplying the component 100 of the kind “a”. In this case where the fifth head 70 also failed to receive the component 100 of the kind “a” to be held by the first head 70, the ninth head 70 is used in place of the first and fifth heads 70, to receive the component 100 of the kind “a” from the above-indicated other tape feeder 92, since the ninth eleventh head 70 is located at the working position K when the fifth head 70 is located at the component-hold-position detecting position C, as indicated in FIG. 11D. Thus, the operation of the ninth head 70 to hold the component 100 of the kind “a” takes place after the operation of the eighth head 70 to hold the component 100 of a kind “g”, and the assignment of the tenth and the following heads 70 to hold the components 100 of respective different kinds “h”, “i”, etc. must be shifted one position, as also indicated in FIG. 19. When the ninth head 70 has been moved to the component-mounting position G, the printed-wiring board 24 is positioned to bring the corresponding mounting spot into alignment with the component-mounting position G, so that the component 100 of the kind “a” is mounted at this mounting spot by the ninth head 70.

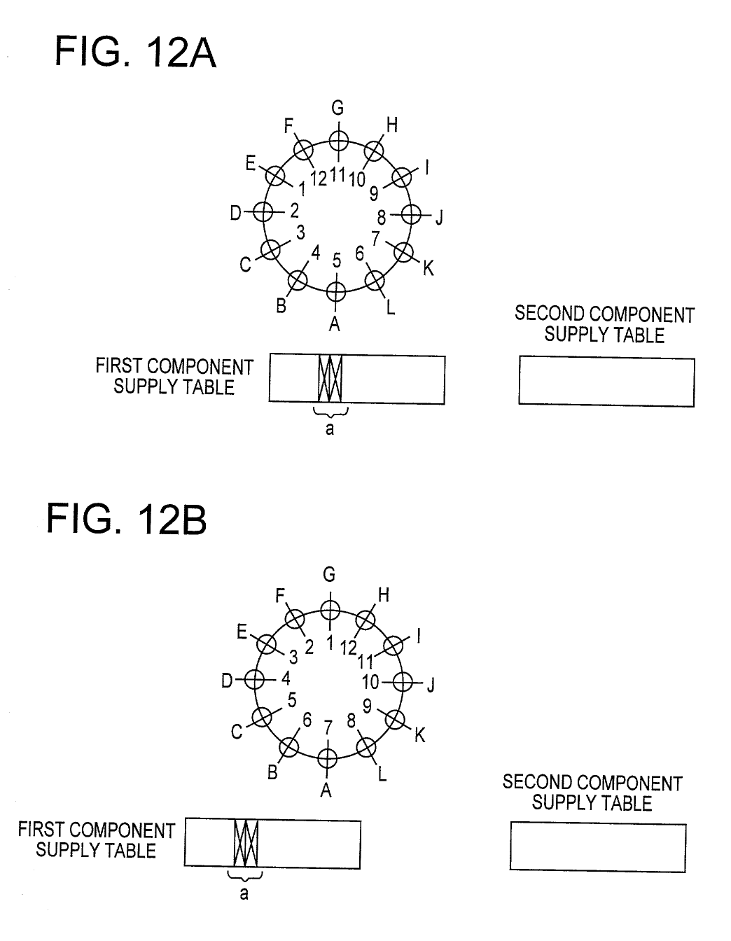

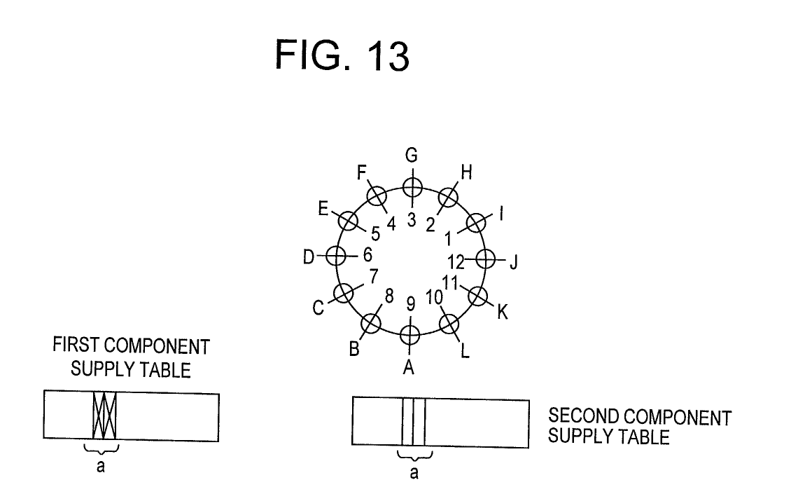

When all of the plurality of tape feeders 92 accommodating the components of the kind “a” have been exhausted on the first component supply table 80, as indicated in FIG. 12A by way of example, the first table 80 now existing in the working area is replaced by the second table 82 which has been held at the standby position. Namely, the first table 80 is moved to its standby position, and the second table 82 is moved into the working area, as indicated in FIG. 13 and used as the operating table. The appropriate set of tape feeders 92 has been set up on the feeder carriage 90 of the second table 82 at the standby position before this second table 82 is moved into the working area. The movement of the second table 82 into the working area takes place concurrently with the movement of the first table 80 to the standby position. When the first table 80 is replaced by the second table 82 due to exhaustion of the tape feeders 92 accommodating the components 100 of the kind “a”, data indicative of this kind “a” and the positions of these tape feeders 92 on the feeder carriage 90 of the first table 80 are stored in the RAM 186. Where the two or more tape feeders 92 accommodating the components 100 of the same kind are mounted on each of the first and second tables 80, 82, such data may be stored in the RAM 186 when each of those tape feeders has been exhausted

Where the exhaustion of the tape feeder or feeders accommodating the components 100 of the kind “a” on the first table 80 is detected due to the failure of the first and fifth heads 70 to receive the component 100 of the kind “a”, the ninth head 70 is used to receive the component 100 of this kind “a” from the appropriate tape feeder 92 on the second table 82, since the ninth head 70 is located at the working position K when the exhaustion is detected with the fifth head 70 located at the component-hold-position detecting position C, as indicated in FIG. 12B. Accordingly, the assignment of the heads 70 to hold the components 100 of the different kinds is shifted, and the kind of the suction nozzle 62 to be used is changed as needed, when the operating table 80, 82 is changed, as well as when the tape feeder 92 to be used on the same table 80, 82 is changed.

Accordingly, the first table 80 is replaced by the second table 82 after the eighth head 70 has received the component 100 of the kind “g” from the appropriate tape feeder 92 of the first table 80. To permit the replacement of the first table 80 with the second table 82, the component mounting device 18 is arranged to reduce the intermittent rotation of the indexing body 42, so that one of the tape feeders 92 accommodating the components 100 of the kind “a” on the second table 82 is moved to the component supply position 150 when the ninth head 70 is moved to the component-receiving position A.

The second table 82 is moved by the second table moving device 86 within the working area so that the tape feeders 92 mounted thereon are sequentially moved to the component supply position 150 in the predetermined order, to supply the components 100 of the different kinds, like the tape feeders 92 on the first table 80. At this time, the first table 80 is held stationary and in the offs state at the standby position. The operation of the second table 82 in the working area to supply the electronic components 100 while the first table 80 is held at rest at the standby position is a second component-supplying step, which is controlled by the control device 180 in a second control mode.

During the operation of the second table 82 to supply the components 100 in the working area, the tape feeders 92 of the first table 80 which have been exhausted are re-loaded or replenished with the appropriate components 100 or replaced with the new ones. The re-loading or replacement of the tape feeders 92 of the first table 80 at the standby position is conducted by the operator, on the basis of information given on the indicator device 196, which is operated according to the data which are stored in the RAM 186 and which relate to the tape feeders 92 that have been exhausted. The re-loading or replacement of the tape feeders 92 in the cooperative same-board table changing mode may be effected in the same manner as in the non-cooperative same-board table changing mode. This re-loading or replenishment is completed before a third component-supplying step is initiated to supply the components 100. When the re-loading or replacement of the tape feeders 92 on the first table 80 is completed, the operator manipulates the input deice 193 to inform the computer 190 that the exhausted tape feeders 92 on the first table 80 have been re-loaded with the components 100 or replaced with the new ones. As a result, the data relating to the exhaustion of the relevant tape feeders 92 stored in the RAM 186 are erased. The re-loaded or replaced tape feeders 92 on the first table 80 are used as needed in the subsequent third component-supplying step, which will be described.

Even if the third component-supplying step is required to be initiated before the re-loading or replenishment of the exhausted tape feeder or feeders 92 on the first table 80 is completed, this third component-supply step is initiated without complete re-loading or replenishment of the exhausted tape feeder or feeders 92. Where a plurality of tape feeders 92 on the first table 80 have been exhausted, the operator is requested to enter data indicative of the completion of re-loading or replenishment of each of the exhausted tape feeders each time the re-loading or replenishment of that tape feeder is completed, prior to the completion of all of the exhausted tape feeders. In this case, this tape feeder may or may not be used in the third component-supplying step. In the present embodiment, this tape feeder is not used in the third component-supplying step.

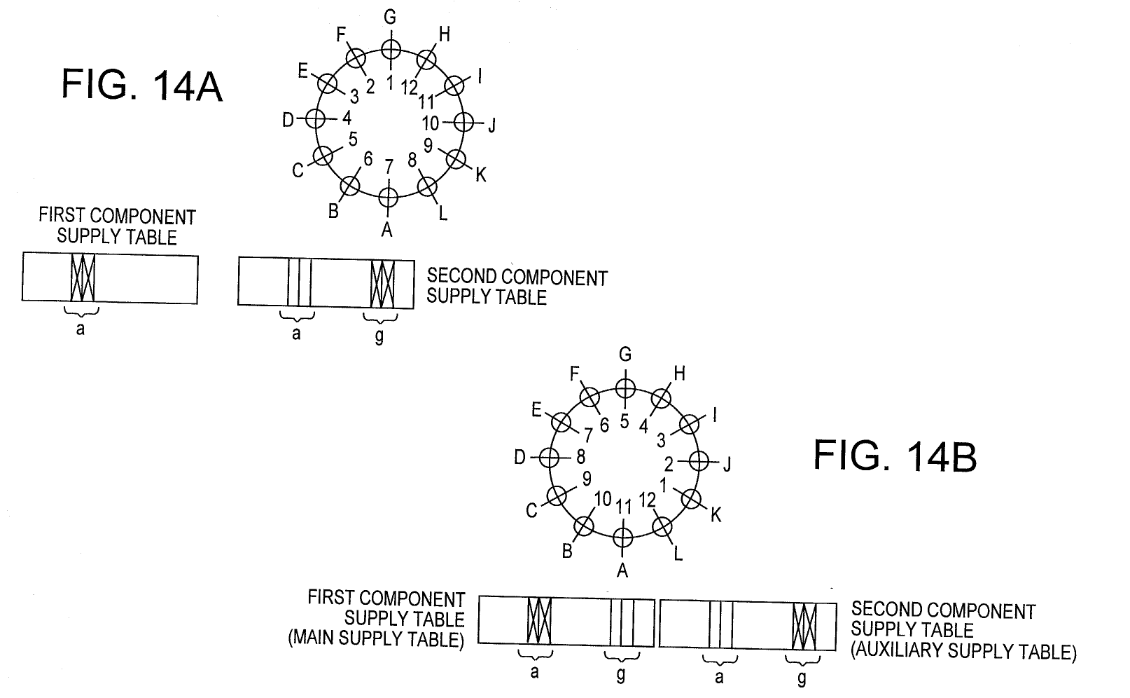

If one of the two or more tape feeders 92 of the second table 82 which accommodate the components 100 of the same kind has been exhausted, the other tape feeder 92 of the second table 82 is used to supply the components 100. When all of the tape feeders 92 of the second table 82 accommodating the components 100 of the relevant kind have been exhausted, the computer 190 checks to see whether the kind of the components 100 all of which have been supplied from the second table 82 is the same as the kind of the components 100 all of which were supplied from the first table 80, that is, to determine whether the kind of the components 100 accommodated in the exhausted tape feeders of the second table 82 can be supplied from the first table 80.

Where all of the components 100 of the kind “g” have been supplied from the second table 82, as indicated in FIG. 14A, this kind “g” is different from the kind “a” of the components 100 all of which were supplied from the first table 80, so that the first table 80 is able to supply the components 100 of the kind “g”. Accordingly, the first table 80 is moved into the working area, as indicated in FIG. 14B, and the second component-supplying step is replaced or followed by the third component-supplying step in which the first and second tables 80, 82 cooperate to supply the necessary components 100. The third component-supplying step is controlled by the control device 180 in a third control mode. Thus, the computer 190 of the control device 180 is arranged to implement a transition-permitting step of checking if the first table 80 is able to supply the components 100 of the kind exhausted on the second table 82, and permitting a transition from the second component-supplying step to the third component-supplying step if the first table is able to supply the components 100 of the kind exhausted on the second table 82.

In the third component-supplying step in the present embodiment, the first and second component supply tables 80, 82 are always moved in synchronization with each other, to supply the necessary components 100, such that the two tables 80, 82 are moved in the same direction at the same speed while the two tables 80, 82 are held adjacent to each other. In the third component-supplying step, the first table 80 which was first moved to the standby position due to exhaustion of at least one of the tape feeders 92 is operated as a main supply table, while the second table 82 is operated as an auxiliary supply table. The main supply table is moved such that the tape feeders 92 except the once exhausted one or ones are sequentially moved to the component supply position 150, to supply the necessary components 100 except those of the exhausted tape feeder or feeders. The auxiliary supply table is moved such that the tape feeders 92 accommodating the components 100 of the kinds that cannot be supplied from the main supply table are moved to the component supply position 150, to supply those components 100. In the third component-supplying step, too, the components 100 are supplied from the component supply tables 80, 82, in the order in which the tape feeders 92 are arranged in the component supply tables 80, 82. When the second component-supplying step is followed by the third component-supplying step, too, the assignment of the component holding heads 70 to hold the components 100 of the different kinds is shifted, and the kind of the suction nozzle 62 to be used is changed as needed, when the operating table 80, 82 is changed, as well as when the first component-supplying step is followed by the second component-supplying step.

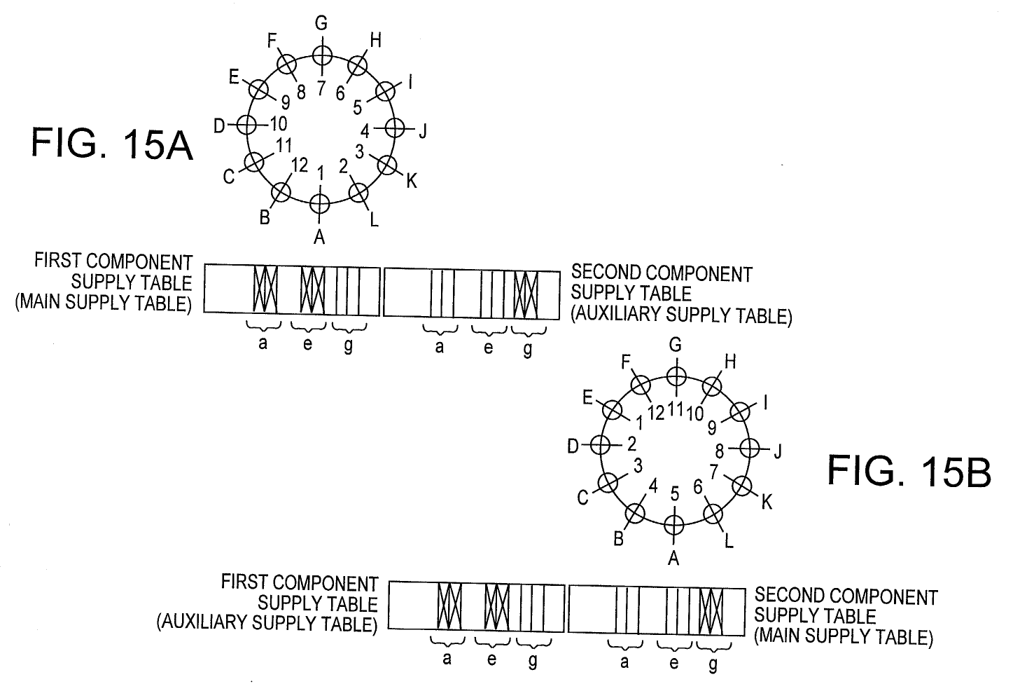

When all of the tape feeders 92 of the first table 80 accommodating the components 100 of the kind “e” (different from the kind “g” of the components exhausted on the second table 82) have been exhausted, as indicated in FIG. 15A, the second table 82 is used as the main supply table to supply components of the kind “e”, while the first table 80 is used as the auxiliary supply table, as indicated in FIG. 15B. The detection of the exhausted tape feeders 92, the shift of the assignment of the heads 70 and the change of the kind of the suction nozzle 62 are effected in the same manner as in the first or second component-supplying step in which the first or second table 80 is used to supply the components 100.

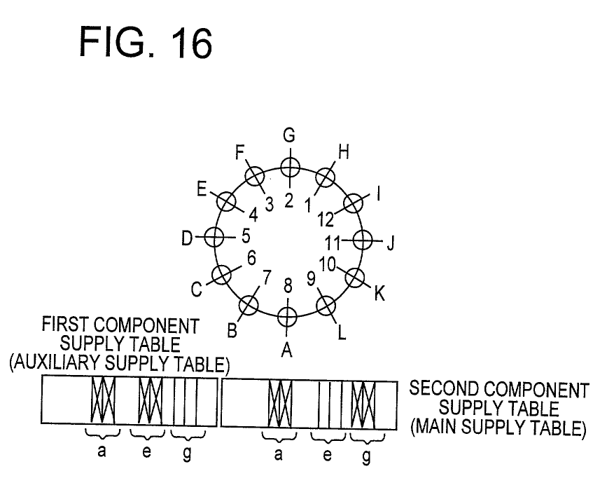

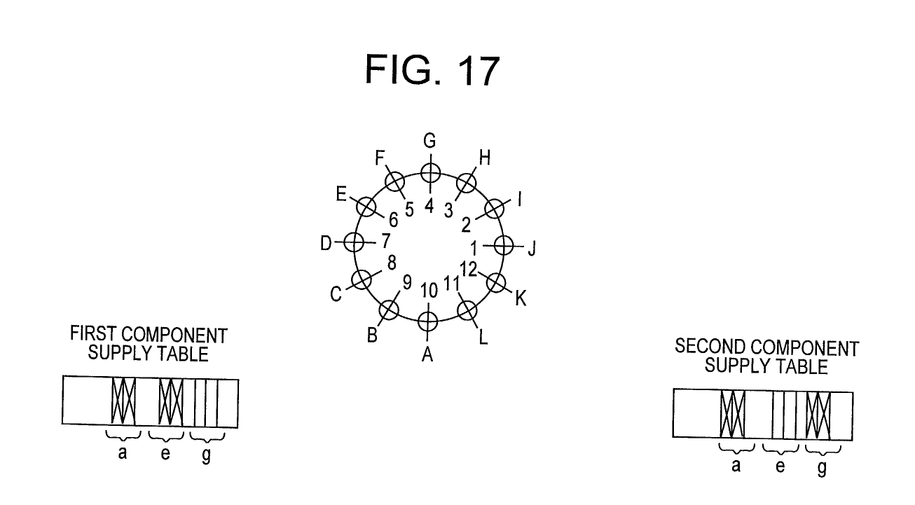

The first and second tables 80, 82 are alternately used as the main and auxiliary supply tables, upon detection of exhaustion of the main supply table of the components 100 of any kind. This alternate use of the first and second tables 80, 82 as the main supply table is continued as long as the components of the kind that cannot be supplied from the main supply table can be supplied from the auxiliary supply table. In the third component-supplying step implemented in the third control mode, the necessary components 100 of the different kinds can be continuously supplied, without having to interrupt the component supplying operation of the component supplying device 20 immediately after some of the tape feeders 92 have been exhausted on both of the first and second tables 80, 82. Thus, the third component-supplying step makes it possible to reduce a need of interrupting the component supplying operation and thereby effectively reduce the deterioration of the component supplying efficiency of the device 20. It is particularly appreciated that the exhausted tape feeders 92 on the first table 80 held at the standby position are re-loaded with the components 100 or replaced with the new ones, in the second component-supplying step, so that the re-loaded or replaced tape feeders 92 on the first table 80 can be used in the third component-supplying step if the re-loading or replacement is completed prior to the initiation of the third component-supplying step. Accordingly, the present arrangement makes it possible to further reduce the need of interrupting the component supplying operation due to exhaustion of both of the main and auxiliary tables 80, 82 of the same kind of components 100, permitting the component supplying device 20 to continuously supply the necessary components 100 for a prolonged length of time, and resulting in significant reduction of the required time of interruption of the component supplying operation.

Where both of the first and second tables 80, 82 have been exhausted of the same kind of components 100, for example, after all of the components 100 of the kind “a” have supplied from supplied from the first and second tables 80, 82, as indicated in FIG. 16, the operation of the component supplying device 20 is automatically interrupted, and the operation of the component mounting device 18 on the printed-wiring board 24 is interrupted, since neither of the two tables 80, 82 is able to supply the components 100 of that kind “a”. In this case, the first and second tables 80,82 are both moved to their standby positions, for re-loading or replacing the exhausted tape feeders 92, and the indicator device 196 is activated to provide a warning signal and a visual indication, for warning and informing the operator that all of the components 100 of the same kind have been supplied from the two tables 80, 82. Thus, the automatic interruption of the component supplying operation and the activation of the indicator device 196 are considered to be a step of automatically interrupting the operation of the component supplying device 20.

It will be understood that the control device 180 includes a component supply control device operable in the first, second and third control modes to automatically perform the above-described first, second and third component-supplying steps, respectively, according to predetermined control programs and data formulated to mount the predetermined electronic components 100 at the respective mounting spots on the printed-wiring board 24. The operations of the component supply device to control the component supplying operation in the selected one of the first, second and third component-supplying steps include: detection of exhaustion of the tape feeders 92; sequential use of the tape feeders 92 accommodating the components 100 of the same kind on each table 80, 82; replacement of the first table 80, 82 with the second table or vice versa; shift of assignment of the component holding heads 70 to hold the components 100 of the different kinds; change of the kind of the suction nozzle 62 to be used; and changes of the order in which the components 100 are supplied from the component supplying device 20 and mounted on the printed-wiring board 24. The component supply control device includes a feeder-exhaustion detecting device arranged to determine that each tape feeder 92 has been exhausted, if the component holding device in the form of the component holding head 70 has failed to receive the component 100 from that tape feeder 92 two consecutive times. The component supply control device further includes a table-exhaustion detecting device arranged to determine that all of the components 100 of the same kind have been supplied from the component supply table 80, 82, if all of the tape feeders 92 accommodating the components 100 of the same kind have been supplied.

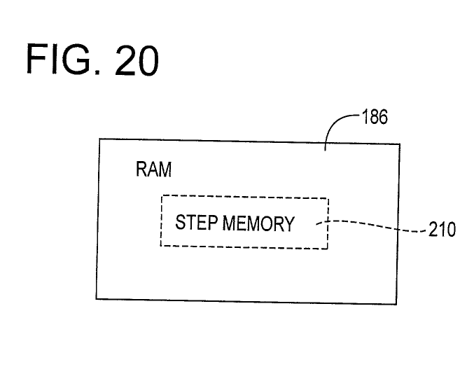

In the embodiment described above, the third component-supplying step is necessarily implemented when the second table operating in the second component-supplying step following the first component-supplying step has been exhausted of the electric components of any kind. However, the switching to the third component-supplying step in this case is not essential. For instance, where the tape feeder 92 exhausted on the first table located 80 at the standby position and held in the off state has been re-loaded with the electric components 100 of the corresponding kind while the electric components 100 are supplied by the second table 82 in the second component-supply step, the component supplying operation can be returned from the second component-supplying step back to the first component-supplying step. The above embodiment is arranged such that when any tape feeder 92 of the second table 82 has been exhausted of the electric components 100 of the corresponding kind, a decision as to whether the first table 80 is able to supply the electric components 100 of the kind exhausted on the second table 82 is made, so that the second component-supplying step is necessarily followed by the third component-supplying step if the affirmative decision is obtained. However, a decision as to whether the first table 80 has any tape feeder 92 which has been exhausted may be made, so that if the negative decision is obtained, it is determined that the component supplying operation was returned from the second component-supplying step back to the first component-supplying step when the tape feeder 92 once exhausted of the electric components on the first table 80 was re-loaded with the electric components. In this case, the third component-supplying step is not implemented, but the second component-supplying step is implemented by using the first table 80 as the operating table and the second table 82 as an assisting table normally located at the standby position. Alternatively, the RAM 186 may include a STEP memory 210 (FIG. 20) for storing PRESENT-STEP data indicative of a presently implemented one of the first, second and third component-supplying steps. In this alternative arrangement, the PRESENT-STEP data are updated to indicate the first component-supplying step when the exhausted tape feeder 92 of the first table 80 has been re-loaded with the electric components 100 in the second component-supplying step. Further alternatively, the second component-supplying step is again implemented with the first table used as the operating table, rather than the third component-supplying step is implemented, when the first table has been re-loaded with the electric components. Substantially the same operations may be performed if the second table 82 has been re-loaded with the electric components 100 in the second component-supplying step implemented again as described above.

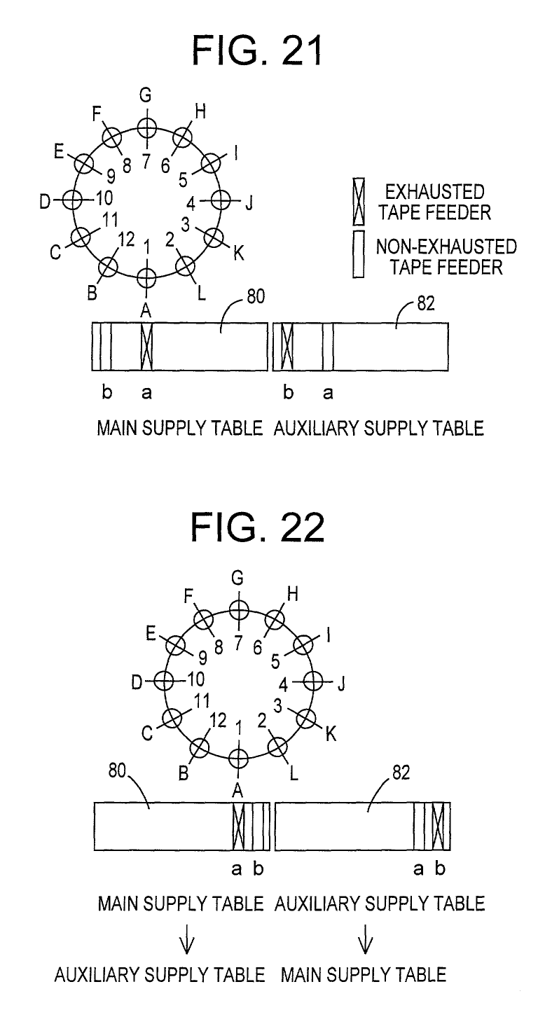

In the embodiment described above, the third component-supplying step is formulated such that the first and second component supply tables 80, 82 are alternately used as the main component supply table to supply the necessary components 100. However, this alternate use of the two tables 80, 82 as the main component supply table in the third component-supplying step is not essential. In an example of FIG. 21, the second table 82 is used as the main component supply table in the second component-supplying step after the tape feeder 92 of the first table 80 has been exhausted of the electric components 100 of the kind “a” in the first component-supplying step. If the tape feeder 92 accommodating the electric components 100 of the kind “b” of the second table 82 has then been exhausted in the second component-supplying step, the second table 82 is used as the auxiliary component supply table while the first table 80 is used as the main component supply table, since a distance of movement of the second table 82 required to supply the electric component 100 of the kind “a” exhausted on the first table 80 is smaller than a distance of movement of the first table 80 required to supply the electric component 100 of the kind “b” exhausted on the second table 82. On the other hand, if the tables 80 and 82 are positioned relative to each other as indicated in FIG. 22 when the tape feeder 92 accommodating the components 100 of the kind “b” of the second table82 has been exhausted in the second component-supplying step, the second table 82 is used as the main component supply table.

The main and auxiliary component supply tables in the third component-supplying step are determined as described above where only one tape feeder 92 of each of the first tables 80, 82 has been exhausted. Where two or more tape feeders 92 have been exhausted on at least one of the first and second tables80, 82, one of the first and second tables is used as the auxiliary component supply table to supply only the electric components of at least one kind exhausted on the other table while the other table is used a the main component supply table, if a total distance of movements of the above-indicated one table required to supply the electric components of the at least one kind exhausted on the other table is smaller than a total distance of movements of the other table required to supply the electric components of the at least one kind exhausted on the one table.

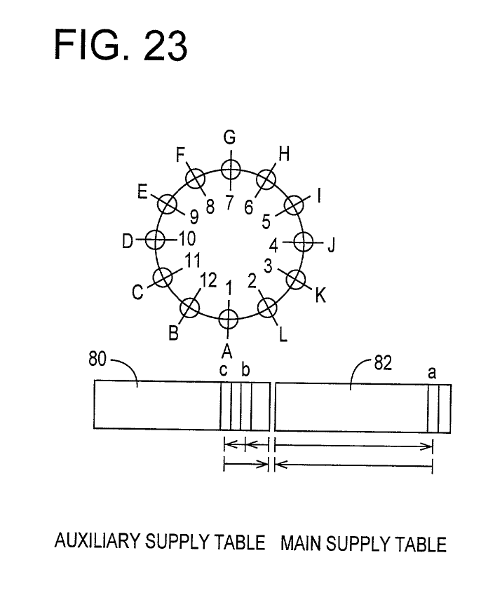

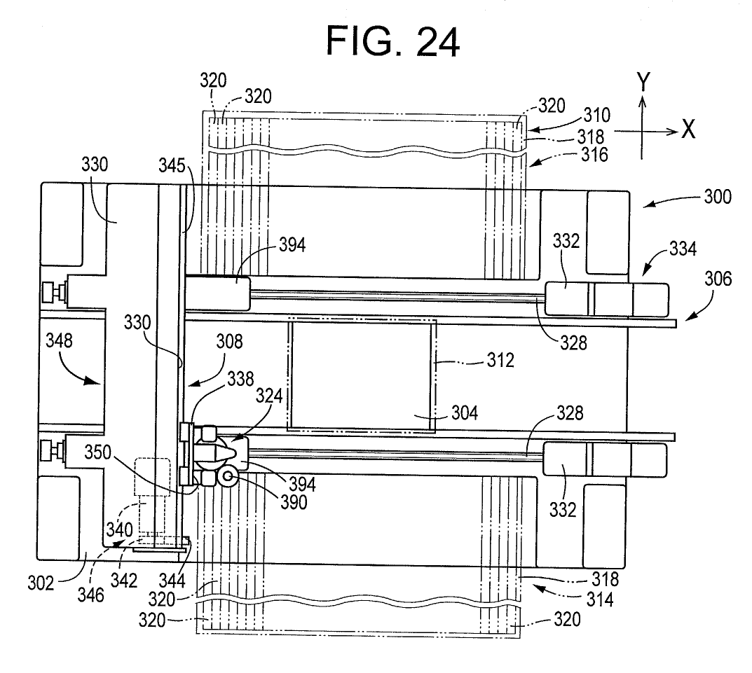

In the first embodiment described above, the component mounting device 18 uses the indexing body 42 which carries the plurality of component holding heads 70 and which is rotated to sequentially move each component holding head 70 to the component-receiving position C, component-mounting positing G, etc., to perform the various working operations such as the operations to hold and mount the components 100. The component mounting device may be modified such that a component holding device is moved by a moving device in a plane parallel to the surface of the printed-wiring board, to a component-receiving position to receive the electric component, and to predetermined mounting spots on the board so that the components are mounted at the mounting spots. Referring to FIGS. 24-26, there will be described a further embodiment of this invention as applied to an electronic-component mounting system which includes a modified component mounting device as described above. In an example of FIG. 23, the two tape feeders 92 accommodating the electric components 100 of the respective kinds “b” and “c” of the second table 82 have been exhausted at one time while the tape feeder 92 accommodating the electric components 100 of the kind “a” of the first table 80 has been exhausted. In this case, a total distance of movements of the first table 80 required to supply the electric components of the kinds “b” and “c” exhausted on the second table 82 is smaller than a distance of movement of the second table 82 required to supply the electric components of the kind “a” exhausted on the first table 80. Accordingly, the first table 80 is used as the auxiliary component supply table while the second table 82 is used as the main component supply table.

The electronic-component mounting system according to the present embodiment is shown generally at 300 in FIG. 24, in which reference sign 302 denotes a machine base or main body of the mounting system 300. On the machine base 302, there are mounted a printed-wiring-board conveyor 306 (PWB conveyor 306), a component mounting device 308, and a component supplying device 310. The PWB conveyor 306 is arranged to move or feed a board or substrate in the form of a printed-wiring board 304 in an X-axis direction (in the right and left direction as seen in FIG. 24). The component mounting device 308 is arranged to mount electronic components on the printed-wiring board 304, and the component supplying device 308 is arranged to supply the component mounting device 306 with the electronic components.

In the present second embodiment, the printed-wiring board 304 is fed by the PWB conveyor 306 such that the board 304 is parallel to the horizontal plane. The board 304 is stopped by a suitable stopper device at a predetermined component-mounting position, and is supported by a board-supporting device in the form of a printed-wiring-board supporting device 312 (PWB supporting device 312) such that a mounting surface of the board 304 on which the electronic components are mounted is held parallel to the horizontal plane. That is, the board 304 is supported such that its mounting surface is parallel to an XY plane which is defined by the X-axis direction indicated above and a Y-axis direction perpendicular to the X-axis direction.

The component supplying device 310 includes a first component supply table 314 and a second component supply table 316, as shown in FIG. 24. These first and second component supply tables 314, 316 are two stationary tables fixedly disposed on the respective opposite sides of the PWB conveyor 306 such that the two supply tables 314, 316 are spaced apart from each other in the Y-axis direction.

Each of the first and second component supply tables 314, 316 includes a feeder support structure 318, and a plurality of component feeders in the form of tape feeders 320 mounted on the feeder support structure 318. Like the tape feeders 92 used in the first embodiment, each of the tape feeders 320 is arranged to feed a carrier tape which accommodates a multiplicity of electronic components of one kind. The feeder support structure 318 is fixed on the machine base 302, and the plurality of tape feeders 320 are mounted on the feeder support structure 318 such that component supply portions of the tape feeders 320 are arranged along a straight line parallel to the X-axis direction. The straight line along which the component supply portions of the tape feeders 320 of the first component supply table 314 are arranged is parallel to the straight line along which the component supply portions of the tape feeders 320 of the second component supply table 316. These two straight lines are located symmetrically with each other with respect to the PWB conveyor 306.

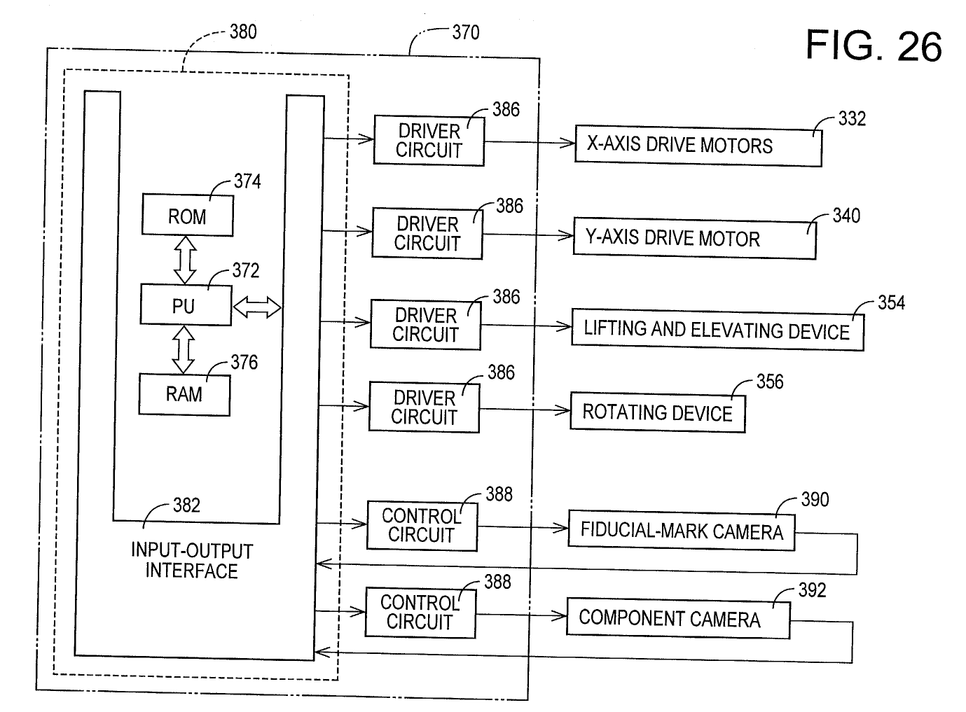

The component mounting device 308 includes a component holding head 324, as shown in FIG. 26. The component holding head 324 is movable along the mutually perpendicular X-axis and Y-axis directions so that each electronic component 326 held by the head 324 is linearly moved to the predetermined mounting spot on the upper or mounting surface of the printed-wiring board 304. This linear movement of the head 324 consists of an X-axis component parallel to the X-axis direction and a Y-axis component parallel to the Y-axis component. To move the component holding head 324, two ballscrews 328 are disposed on the machine base 302 on the respective opposite sides of the PWB conveyor 306, such that the two ballscrews 320 are spaced apart from each other in the Y-axis direction and extend in the X-axis direction, as shown in FIG. 24. These ballscrews 320 are held in engagement with respective ballnuts (not shown) fixed to an X-axis slide 330, and are rotated by respective drive power sources in the form of X-axis drive motors 332, so that the X-axis slide 330 is movable to a desired position in the X-axis direction. As is apparent from FIG. 24, the X-axis slide 330 extends over the PWB conveyor 304, generally in the Y-axis direction, between the first and second component supply tables 314, 316, and the length of the X-axis slide 330 is larger than a distance between the above-indicated two straight lines of the component-supply portions of the tape feeders 320 of the first and second tables 314, 316. The X-axis slide 330 is guided by a guide device, which consists of a guide portion of the machine base 302 in the form of a pair of guide rails (not shown), and a guide block (not shown) provided on the underside of the X-axis slide 330. It will be understood that the above-indicated ballnuts, ballscrews 328, X-axis drive motors 332, etc. cooperate to constitute an X-axis slide positioning device 334.

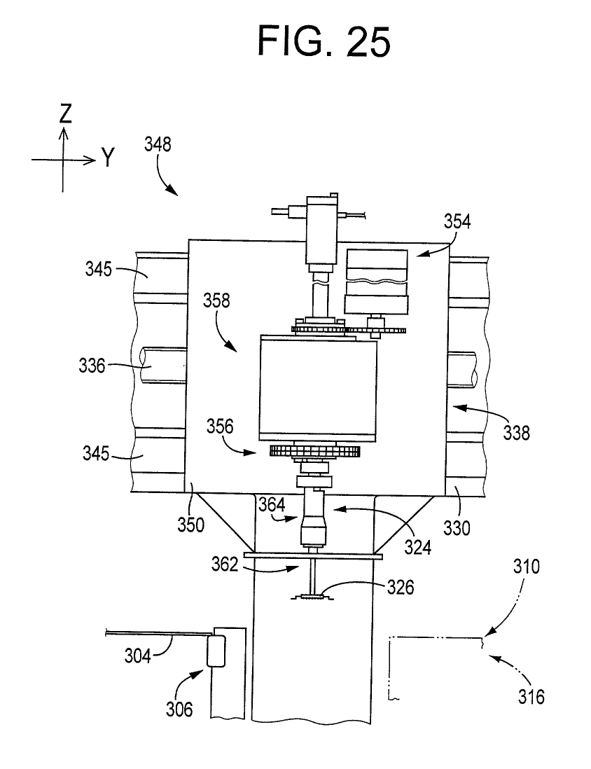

On the X-axis slide 330, there is disposed a ballscrew 336 extending in the Y-axis direction, as shown in FIG. 25. The ballscrew 336 is held in engagement with a ballnut (not shown) fixed to a Y-axis slide 338, and is rotated by a Y-axis drive motor 340 (FIG. 24) through gears 342, 344, so that the Y-axis slide 338 is movable to a desired position in the Y-axis direction while being guided by a pair of guide rails 345. It will be understood that the above-indicated ballnut, ballscrew 336, Y-axis drive motor 340, etc. cooperate to constitute a Y-axis slide positioning device 346, which cooperates with the X-axis slide 330, the X-axis slide positioning device 334 and the Y-axis slide 338 to constitute an XY robot 348. The component holding head 324 is movable by the XY robot 348 to a desired position in the XY plane parallel to the horizontal plane.

On a vertically extending side surface 350 of the Y-axis slide 338, there are mounted the component holding head 324, a lifting and elevating device 354 and a rotating device 356, as shown in FIGS. 24 and 25. The lifting and elevating device 354 is arranged to move the component holding head 324 in the vertical direction, and the rotating device 356 is arranged to rotate the component holding head 324 about a vertical axis of rotation thereof. The component holding head 324, the lifting and elevating device 354 and the rotating device 3456 cooperate to constitute a component mounting unit 358. Although the present embodiment uses only one component mounting unit 358, the electronic-component mounting system 300 may include a plurality of component mounting units which are arranged on the Y-axis slide 338, in a straight row parallel to the Y-axis direction.

The component holding head 324 provided in the present embodiment includes a suction nozzle 362, and a nozzle holder 364 for holding the suction nozzles 362, as shown in FIG. 25. The suction nozzle 362 is arranged to hold the electronic component 326 by suction under a negative pressure. The component mounting unit 358 is constructed as disclosed in Japanese Patent No. 3093339.

The present electronic-component mounting system 300 includes a control device 370 shown in the block diagram of FIG. 26. Like the control device 180, the control device 370 is principally constituted by a computer 380 incorporating a PU 372, a ROM 374, a RAM 376 and a bus interconnecting these elements 380, 374, 376. To the bus, there is connected an input-output interface 382 to which are connected through driver circuits 396 various actuators such as the X-axis and Y-axis drive motors 332, 340. In the present embodiment, servomotors are used as the X-axis drive motors 332 and other actuators. These servomotors are provided with respective rotary encoders to detect the operating angles of the servomotors. However, the servomotors may be replaced by stepping motors. Linear motors may be used in place of such rotary electric motors.

To the input-output interface 382, there also connected through control circuits 388 a fiducial-mark camera 390 and a component camera 392. The fiducial-mark camera 390 is fixedly disposed on the Y-axis slide 338, as schematically shown in FIG. 24, and is moved with the XY robot 348 to an appropriate position in the XY or horizontal plane, to take images of fiducial marks (not shown) provided on the printed-wiring board 304. The component camera 392, which is not shown in FIGS. 24 and 25, is also fixedly disposed on the Y-axis slide 338, and is moved with the suction nozzle 362, to take an image of the electronic component 326 as held by the suction nozzle 362, when the component camera 392 is moved over one of two prisms 394 which are provided at respective Y-axis positions aligned with the positions of the respective two ballscrews 328. An operation of the component camera 392 to take the image of the electronic component 326 is disclosed in Japanese Patent No. 2824378.

In the present electronic-component mounting system 300, the electronic components 326 are mounted on the printed-wiring board 304, such that the component holding head 324 is moved by the XY robot 348 to an appropriate position to receive the electronic component 326 from a selected one of the first and second component supply tables 314, 316 of the component supplying device 310, before the electronic component 326 is subsequently mounted on the board 304. To hold the electronic component 326, the component holding head 324 is moved to the position right above the component-supply portion of the tape feeder 320 from which the electronic component 326 is received. The component holding head 324 is then lowered for the suction nozzle 362 to hold the electronic component 326 by suction, and the component holding head 324 is elevated to pick up the electronic component 326 from the tape feeder 320.

While the component holding head 324 holding the electronic component 326 is moved to the corresponding mounting spot on the printed-wiring board 304, the component camera 392 is operated to take the image of the electronic component 326, so that center position errors ΔXE and ΔYE and an angular positioning error Δθ of the electronic component 326 as held by the suction nozzle 362. The angular positioning error Δθ is eliminated by rotation of the suction nozzle 326 by the rotating device 356, and the center position errors ΔXE and ΔYE are eliminated by compensating the distances of movements of the component holding head 324 in the X-axis and Y-axis directions to the mounting spot on the board 304. The distances of movement of the head 324 are further compensated for eliminating horizontal positioning errors ΔXP and ΔYP of the mounting spot on the board 304, and horizontal positioning errors of the electronic component 326 which are caused by rotation of the suction nozzle 326 to eliminate the angular positioning error Δθ. When the component holding head 324 has reached the appropriate mounting spot on the board 304, the head 324 is lowered to mount the electronic component 326 at the mounting spot on the board 304.

The component supplying device 310 including the first and second component supply tables 314, 316 is operable in a selected one of the four table changing modes, as in the first embodiment, to supply the electronic components 326 to be mounted on the printed-wiring board 304. In the present second embodiment, however, the supply tables 314, 316 are held stationary, so that the component holding head 324 is moved to a selected one of the two supply tables 314, 316, in the selected table changing mode.

The cooperative same-board table changing mode in the present embodiment will be briefly discussed. In this cooperative same-board table changing mode, the same sets of tape feeders 320 accommodating the electronic components 326 of different kinds are arranged in the same predetermined order on both of the first and second component supply tables 314, 316. Initially, the component supplying device 310 is operated so as to perform the first component-supply step such that the electronic components 326 are supplied from the first table 314. That is, the component holding head 324 is moved to positions right above the component-supply portions of the appropriate tape feeders 320 on the first table 314, so that the electronic components 326 of the different kinds are received from the respective tape feeders 320.

When all of the electronic components 326 of a given kind on the first component supply table 314 have been supplied, the necessary electronic components 326 are then supplied from the second table 316. The exhaustion of each tape feeder 320 is detected in the same manner as in the first embodiment, by checking whether the suction nozzle 362 of the component holding head 324 has received the electronic component 326 from that tape feeder 320. Where the suction nozzle 326 has failed to receive the electronic component 326 due to exhaustion of the relevant tape feeder 320, this fact can be detected since no image of the electronic component 326 is taken by the component camera 392. In this case, the component holding head 324 is operated again to try to receive the electronic component 326 from the same tape feeder 320. If the suction nozzle 326 of the head 324 has again failed to receive the electronic component 326 from the same tape feeder 320, it is determined that the relevant tape feeder 320 has been exhausted of the components 100 of the corresponding kind. If another tape feeder 320 accommodating the same kind of components 326 is provided on the first table 314, the components 326 of that kind are supplied from the first table 314.

Where all of the tape feeders 320 accommodating the components 326 of the same kind have been supplied from the first table 314, the second table 316 is used in place of the first table 314, to supply the necessary components 326. That is, the component supplying device 310 is operated so as to perform the second component-supplying step. Where all of the tape feeders 320 accommodating the components 326 of the same kind have been supplied from the second table 316, the component supplying device 310 is operated so as to perform the third component-supplying step in which the first and second component supply tables 314, 316 cooperate to supply the necessary components 326 of different kinds. In the third component-supplying step, the first table 314 is first operated as the main supply table, for instance. Where all of the components 326 of the same kind have been supplied from the first and second tables 314, 316, the operation of the component supplying device 310 to supply the components 326 is interrupted or suspended. Since the component supply tables 314, 316 are stationary, the tape feeders 320 on these tables can be re-loaded with the components 326 or replaced with new ones during the operation of the component supplying device 310 in the third component-supplying step in the cooperative same-board table changing mode. However, the re-loading or replacement of the tape feeders 320 may or may not be implemented in the third component-supplying step. The cooperative operations of the two component supply tables 314, 316 permit continuous supply of the necessary electronic components 326 of different kinds for a comparatively long time, thereby reducing a need of interrupting the operation of the component supplying device 310.

In the present electronic-component mounting system arranged to move the component holding device in the plane parallel to the printed-wiring board, too, it is not essential to implement the third component-supplying step when any tape feeder on the second component supply table has been exhausted of the electric components in the second component-supplying step followed by the first component-supplying step. Like the electronic-component mounting system according to the first embodiment wherein the indexing body carrying a plurality of component holding devices and is rotated to move each component holding device the various working positions such as the component-receiving position and the component-mounting position, the electronic-component mounting system wherein the component holding device is moved in the plane parallel to the printed-wiring board may be arranged to return the component supplying operation from the second component-supplying step back to the first component-supplying step.

In the first embodiment wherein the first and second component supply tables 80, 82 are movable, the main supply table and the auxiliary supply table are always moved in the same direction at the same speed such that the two tables are kept adjacent to each other. However, this manner of movements of the two movable tables 80, 82 is not essential. For instance, the auxiliary supply table may be controlled such that this auxiliary supply table is normally held at the standby position, and is moved into the working area only when the necessary component 326 should be supplied from the auxiliary supply table. In this case, for instance, the first and second tables 80, 82 are controlled such that the main supply table presently located in the working area is moved to its standby position while at the same time the auxiliary supply table is moved from its standby position into the working area, to supply the necessary component 326. After the necessary component 326 has been supplied from the supply table in the working area, this table is returned to the standby position again while at the same time the supply table which has been at the standby position is returned to the working area. Alternatively, the auxiliary supply table alone is first moved by a suitable distance toward the working area, and is then moved to the position of the appropriate tape feeder 92 while the main supply table is moved toward its standby position.

In the illustrated embodiments, the electronic components of different kinds are supplied in the third component-supplying step, in the order of mounting of the components on the printed-wiring board, and the auxiliary supply table is used to supply the component of a kind which cannot be supplied by the main supply table in the absence of any component of that kind. However, this arrangement is not essential. For instance, the components of different kinds which are accommodated in the tape feeders on the main supply table and which are to be mounted on the printed-wiring board are first supplied from the main supply table, and then the components of the kinds that cannot be supplied from the main supply table are supplied from the auxiliary supply table. In this case, the main and auxiliary supply tables may be always moved together in synchronization with each other, or alternatively the main supply table is held in the working area to supply the necessary components while the auxiliary supply table is held at the standby position, and after the supply of the components from the main supply table is completed, the auxiliary supply table is moved into the working area while the main supply table is moved to the standby position. Further alternatively, a movement of the auxiliary supply table toward the working area is initiated immediately before the completion of supply of the components from the main supply table, and the auxiliary supply table is then moved into the working area to supply the necessary component while at the same time the main supply table is moved to the standby position.

In the second component-supplying step, the re-loading or replacement of the tape feeder or feeders on the first component supply table is not essential. In the first embodiment wherein the first and second tables 80, 82 are movable, the exhausted tape feeder or feeders on the supply table if held at the standby position in the second component-supplying step may or may not be re-loaded with the components or replaced with new ones.

If any tape feeder on the operating table operated in the non-cooperative same-board table changing mode has been exhausted before all of the exhausted tape feeders on the non-operating table at the standby position have not been re-loaded with the components or replaced with new ones, the table changing mode may be changed from the non-cooperative same-board table changing mode to the cooperative same-board table changing mode. Namely, the component supplying device is operated in the non-cooperative same-board table changing mode with the first and second tables being alternately used to supply the necessary components, as long as the re-loading or replacement of the exhausted tape feeder or feeders on the non-operating table can be completed before the non-operating table is required to be used as the operating table. When the re-loading or replacement on the non-operating table cannot be completed before this table is required to be used as the operating table, the table changing mode of the component supplying device is changed to the cooperative same-board table changing mode in which the two tables cooperative to supply the necessary components. In this case, the table changing mode may be changed either manually in response to a signal generated as a result of an operation by the operator, or automatically by the control device.

Further, the feeder-exhaustion detecting device for detecting the exhaustion of each tape feeder may be arranged to count the number of the electronic components which have been supplied, and determine whether all of the components have been supplied from the tape feeder, by comparing the counted number of the supplied components with a predetermined value, which is typically equal to the number of the components accommodated in the tape feeder. Where only one tape feeder is used to accommodate the components of the same kind, the feeder-exhaustion detecting device constitutes a table-exhaustion detecting device for detecting that each component supply table has been exhausted of the components of the same kind. Where a plurality of tape feeders are used to accommodate the components of the sake kind, the table-exhaustion detecting device is constituted by the feeder-exhaustion detecting device and a portion of the control device which is assigned to detect the exhaustion of all of the tape feeders accommodating the components of the same kind on the relevant table, on the basis of the output signal of the feeder-exhaustion detecting device. The feeder-exhaustion detecting device may include a photoelectric sensor or other sensor capable of detecting the presence or absence of the electronic component at the component-supply portion of the relevant feeder.

The length of the covering tape 110 which has been removed from the carrier tape 104 may be accommodated in a storage container provided on the tape feeder 92, 320, rather than wound on the take-up device 112.

The feeding device provided one each tape feeder 92, 320 for feeding the carrier tape 104 may include its own drive power source, which is operated to feed the carrier tape 104 independently of the operation of the component mounting device 18, 308.

The ballscrews 134, 136 of the first and second table moving devices 84, 86 in the first embodiment are rotated by the respective drive motors 138, 140, these two ballscrews 134, 136 may be selectively rotated by a single drive motor such that a rotary motion of the drive motor is transmitted to a selected one of the two ballscrews 134, 136 through a suitable clutch. In this case, the first and second component supply tables 80, 82 cannot be moved simultaneously, so that the first and second tables are moved at different times in the third component-supplying step.

The table guiding device and the first and second table moving devices are not limited to the guide rail 130 and the drive devices including the ballscrews 134, 136 and drive motors 138, 140 which are used in the first embodiment, and may be suitably arranged as needed.

In the first embodiment, the first and second component supply tables 80, 82 are moved by the respective first and second table moving devices 84, 86. However, a single table moving device may be used commonly for the two component supply tables 80, 82. In this case, the single table moving device may including a movable member, a drive device operable to move the movable member, and a switching device arranged to connect the movable member to a selected one or both of the first and second component supply tables, as disclosed in JP-B2-2-53955. In operation of this table moving device, the movable member is connected to the selected one of the first and second tables, to move the first table in the first component-supplying step, and to move the second table in the second component-supplying step. In the third component-supplying step, the movable member is connected to both of the two tables, to move the two tables together.

The component supplying device and method according to the present invention are applicable to any system other than an electronic-component mounting system, provided that the system includes two component supply tables.

It is to be understood that the present invention may be embodied with various other changes, modifications and improvements, such as those described in the SUMMARY OF THE INVENTION, which may occur to those skilled in the art, without departing from the spirit and scope of the invention defined in the following claims:

### APPENDIX

### CONCISE EXPLANATION UNDER RULE 98

JP-B2-8-21791

A concise explanation of this document is provided on pages 1-4 of the specification.

JP-A-10-200296

This document discloses a component supplying device including alternately used two main component supply tables 5L, 5R carrying component feeders 10, and auxiliary component supply table 11 from which components 15 can be supplied onto exhausted component feeders 10 on the main supply table 5 at standby position, by suction nozzle 12 mounted on XY robot 12 movable between the auxiliary component supply table 11 and the main supply table at the standby position.

What is claimed is:

1. A method of supplying electric components, comprising the steps of:
a preparing step of preparing two component supply tables each including a feeder support structure and a plurality of component feeders mounted on said feeder support structure, each of said plurality of component feeders accommodating a group of electric components of one kind and arranged to successively supply the electronic components from a component-supply portion thereof such that a combination of electric components of different kinds that can be supplied from said plurality of component feeders on one of said two component supply tables is the same as that of electric components of different kinds that can be supplied from said plurality of component feeders on the other component supply table;
a first component-supplying step in which a first table which is one of said two component supply tables is operated to supply the electric components, while a second table which is the other of said two component supply tables is held in an off state;
a second component-supplying step in which said first table is held in an off state while said second table is operated to supply the electric components, after said first table has been exhausted of the electric components of any kind; and
a third component-supplying step in which said first and second tables cooperate to supply the electric components after said second table has been exhausted of the electric components of any kind.

2. The method according to claim 1, further comprising a transition-permitting step implemented upon exhaustion of said second table of the electric components of any kind, to check if said first table is able to supply the electric components of the kind exhausted on said second table, and permit a transition from said second component-supplying step to said third component-supplying step.

3. The method according to claim 1, further comprising a ceasing step of automatically ceasing a supply of the electric components from said first and second tables, when the first and second tables have become unable to supply the electric components of the same kind.

4. The method according to claim 3, wherein said ceasing step further comprises informing an operator of a system including said first and second tables, that the supply of the electric components from the first and second tables has been automatically ceased.

5. The method according to claim 1, wherein said third component-supplying step is implemented such that said first table is primarily used to supply the necessary electric components, and said second table is used to supply only the electric components of at least one kind which cannot be supplied by said first table.

6. The method according to claim 1, wherein said third component-supplying step is implemented such that said second table is primarily used to supply the necessary electric components, and said first table is used to supply the only the electric components of at least one kind which cannot be supplied by said second table.

7. The method according to claim 1, wherein said plurality of component feeders of each of_said first and second tables includes at least one set of component feeders, each of said at least one set consisting of a plurality of component feeders which accommodate the electric components of one kind, and wherein one of said first and second tables is used as an operating table when all of said plurality of component feeders of any one of said at least one set of the other of said first and second tables have been exhausted of the electric components.

8. The method according to claim 1, wherein said first and second tables are movable in a direction in which the component-supply portions of said plurality of component feeders of each of said first and second tables are arranged, and when one of said first and second tables is used as an operating table to supply the electric components of different kinds, said operating table is moved such that a selected one of said plurality of component feeders of said operating table is located at a predetermined component supply position, while the other of said first and second table is held in its off state.

9. The method according to claim 8, wherein said third component-supplying step is implemented such that when one of said first and second tables is used as an auxiliary component supply table to supply only the electric components of at last one kind exhausted on the other of said first and second tables, while said other table is used as a main component supply table to supply the electric components of at least one kind which has been exhausted on the above-indicated one table and which is different from said at least one kind exhausted on said other table, if a total distance of movements of said one table required to supply the electric components of said at least one kind exhausted on said other table is smaller than a total distance of movements of said other table required to supply the electric components of said at least one kind exhausted on one table.

10. The method according to claim 8, wherein said third component-supplying step is implemented such that said first and second tables are moved in a same direction at a same speed in at least a portion of a movement of one of said first and second tables to supply the electric component, such that said first and second tables are held adjacent to each other during movements thereof.

11. The method according to claim 1, further comprising a re-loading step in which at least one exhausted feeder if included in said plurality of component feeders of one of said first and second tables which is held in said off state is re-loaded with the electric components of the corresponding at least one kind.

12. The method according to claim 11, wherein when all of said at least one exhausted feeder of said first table held in said off state have been re-loaded with the electric components in said second component-supplying step, said second component-supplying step is treated as said first component-supplying step in a subsequent control of operations of said two component supply tables.

13. A method of mounting electric components on a printed board, the method comprising supplying an electric-component mounting device with the electric components according to a method defined in any one of claims 1-12.

14. A component supplying device comprising:
two component supply tables each including a feeder support structure and a plurality of component feeders mounted on said feeder support structure, each of said plurality of component feeders accommodating a group of electric components of one kind and arranged to successively supply the electric components from a component-supply portion thereof; and
a component supply control device operable in control modes including at least: (a) a first control mode in which a first table which is one of said two component supply tables is operated to supply the electric components, while a second table which is the other of said two component supply tables is held in an off state; (b) a second control mode in which said first table is held in an off state while said second table is operated to supply the electric components, after said first table has been exhausted of the electric components of any kind; and (c) a third control mode in which said first and second tables cooperate to supply the electric components after said second table has been exhausted of the electric components of any kind.

15. A component mounting system comprising:
a component supplying device as defined in claim 14;
a board supporting device arranged to hold a printed board; and
a component mounting device operable to receive the electric components from said component supplying device, and mount the electric components on said printed board supported by said board supporting device.

16. The component mounting system according to claim 15, wherein said component mounting device comprises:
a plurality of component holding device operable to hold the electric components; and
a turning device operable to turn said plurality of component holding devices about a common axis of turning, such that each of said component holding devices is sequentially stopped at at least a predetermined component-receiving position at which said each component holding device receives the electric components from said component supplying device, and a predetermined component-mounting position at which said each component holding device transfers the electric components onto the printed board supported by said board supporting device.
